(19) United States
(12) Patent Application Publication
(10) Pub. No.: US 2026/0090040 A1
(43) Pub. Date: Mar. 26, 2026

(54) SEMICONDUCTOR DEVICE AND METHODS OF FORMATION

(71) Applicant: Taiwan Semiconductor Manufacturing Company, Ltd., Hsinchu (TW)

(72) Inventors: Pin-Wen CHEN, Keelung City (TW); Chih-Chieh LEE, Taipei City (TW); Wei-Jung LIN, Hsinchu City (TW); Hung-Chang HSU, Kaohsiung (TW); Li-Wei CHU, New Taipei City (TW); Chun-Hsien HUANG, Hsinchu (TW); Chih-Chien CHI, Hsinchu City (TW); Chih-Wei CHANG, Hsin-Chu (TW); Ming-Hsing TSAI, Chu-Pei City (TW); Pei Shan CHANG, Taipei (TW); Pei-Wen WU, Xinfeng Township (TW)

(21) Appl. No.: 19/033,005

(22) Filed: Jan. 21, 2025

Related U.S. Application Data
(60) Provisional application No. 63/698,669, filed on Sep. 25, 2024.

(51) Int. Cl. H10D 62/10; H10D 30/00; H10D 30/01; H10D 30/43; H10D 30/67; H10D 64/01; H10D 84/01; H10D 84/83

(52) U.S. Cl. CPC H10D 62/121; H10D 30/014; H10D 30/0191; H10D 30/43; H10D 30/502; H10D 30/6735; H10D 64/017; H10D 84/013; H10D 84/0135; H10D 84/832

(57) ABSTRACT

A source/drain region is formed for a nanostructure transistor of a semiconductor device such that the source/drain region includes a metal core. The metal core provides a greater amount of surface area for a front side source/drain contact and a back side source/drain contact to be coupled to the source/drain region than if the source/drain region were fully filled in with epitaxially-grown semiconductor material. The increased contact surface area provides for reduced contact resistance between the source/drain region and the front side and back side source/drain contacts because of the less-restricted current flow path between the source/drain region and the front side and back side source/drain contacts. The reduced contact resistance between the source/drain region and the front side and back side source/drain contacts enables a greater power efficiency to be achieved for the nanostructure transistor and/or enables increased switching speeds to be achieved for the nanostructure transistor.

### CROSS-REFERENCE TO RELATED APPLICATION

This Patent Application claims priority to U.S. Provisional No. 63/698,669, filed on Sep. 25, 2024, and entitled “SEMICONDUCTOR DEVICE AND METHODS OF FORMATION.” The disclosure of the prior Application is considered part of and is incorporated by reference into this Patent Application.

### BACKGROUND

As semiconductor device manufacturing advances and technology processing nodes decrease in size, transistors may become affected by short channel effects (SCEs) such as hot carrier degradation, barrier lowering, and quantum confinement, among other examples. In addition, as the gate length of a transistor is reduced for smaller technology nodes, source/drain (S/D) electron tunneling increases, which increases the off current for the transistor (the current that flows through the channel of the transistor when the transistor is in an off configuration). Silicon (Si)/silicon germanium (SiGe) nanostructure transistors such as nanowires, nanosheets, and gate-all-around (GAA) devices are potential candidates to overcome short channel effects at smaller technology nodes. Nanostructure transistors are efficient structures that may experience reduced SCEs and enhanced carrier mobility relative to other types of transistors.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1C are diagrams of an example implementation of a fin definition process described herein.

FIG. 2 is a diagram of an example dummy gate structure formation process described herein.

FIG. 3 is a diagram of an example implementation of a source/drain recess formation process described herein.

FIGS. 4A and 4B are diagrams of an example implementation of an inner spacer formation process described herein.

FIGS. 5A and 5B are diagrams of an example implementation of a source/drain region formation process described herein.

FIG. 6 is a diagram of an example implementation of an interlayer dielectric formation process described herein.

FIGS. 7A and 7B are diagrams of an example implementation of a replacement gate process described herein.

FIGS. 8A-8I are diagrams of an example implementation of a source/drain contact formation process described herein.

FIG. 9 is a diagram of an example implementation of a semiconductor device described herein.

FIGS. 10A-10I are diagrams of an example implementation of forming a semiconductor device described herein.

FIGS. 11A-11G are diagrams of an example implementation of forming a semiconductor device described herein.

FIGS. 12A-12F are diagrams of an example implementation of forming a semiconductor device described herein.

FIG. 13 is a diagram of an example implementation of a semiconductor device described herein.

FIGS. 14A-14F are diagrams of an example implementation of forming a semiconductor device described herein.

FIG. 15 is a flowchart of an example process associated with forming a semiconductor device described herein.

FIG. 16 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Nanostructure transistors (e.g., nanowire transistors, nanosheet transistors, GAA transistors, multi-bridge channel transistors, nanoribbon transistors, and/or other types of nanostructure transistors) may overcome one or more of the above-described drawbacks of some types of transistors. However, nanostructure transistors face fabrication challenges that can cause performance issues, manufacturing yield issues, and/or device failures.

For example, various parts of a nanostructure transistor may be susceptible to increased resistance as feature sizes are reduced. One such part of a nanostructure transistor that is susceptible to increased resistance is the connection between a source/drain region of the nanostructure transistor and a source/drain contact formed on the source/drain region. As the sizes (e.g., the lateral widths) of the source/drain region and the source/drain contact are reduced, the contact surface area between the source/drain region and the source/drain contact is reduced. The reduced contact surface area between the source/drain region and the source/drain contact restricts the flow of electrons between the source/drain region and the source/drain contact, which increases current crowding around the source/drain region and the source/drain contact.

The increased current crowding results in increased contact resistance between the source/drain region and the source/drain contact. This can lead to reduced power efficiency for the nanostructure transistor and/or reduced switching speeds for the nanostructure transistor, among other examples.

In some implementations described herein, a source/drain region is formed for a nanostructure transistor of a semiconductor device such that a hollow core extends through the source/drain region from a top of the source/drain region to a bottom of the source/drain region. The hollow core is achieved by partial epitaxial growth of one or more epitaxial layers of the source/drain region. A metal core of the source/drain region is formed in the hollow core and electrically coupled to a front side source/drain contact of a nanostructure transistor such that electrically conductive material is recessed within the source/drain region. This provides a greater amount of contact surface area between the front side source/drain contact and the source/drain region than if the source/drain region were fully filled in with epitaxially-grown semiconductor material. Moreover, the metal core extending through the source/drain region enables the metal core to be connected to a back side source/drain contact on a back side of the semiconductor device such that the source/drain region is electrically connected to interconnect layers on a front side of the semiconductor device and on the back side of the semiconductor device.

The increased contact surface area provides for reduced contact resistance between the source/drain region and the front side and back side source/drain contacts because of the less-restricted current flow path between the source/drain region and the back side and front side source/drain contacts. In this way, the reduced contact resistance enables a greater power efficiency to be achieved for the nanostructure transistor and/or enables increased switching speeds to be achieved for the nanostructure transistor, among other examples. Moreover, the metal core fully extending through the source/drain region enables a single metal silicide layer to be shared by the front side and back side source/drain contacts, which reduces the process complexity, time, and/or cost for forming the semiconductor device.

Additionally and/or alternatively, an increased contact surface area between a source/drain region and a front side source/drain contact of a nanostructure transistor of the semiconductor device may be achieved by etching the source/drain region so that the front side source/drain contact can be recessed within the source/drain region. A multiple-step etch process may be performed to form a recess in the source/drain region such that the recess at least extends below the top-most nanostructure channel of the nanostructure transistor. In some implementations, the recess may be formed in the source/drain region such that the recess extends below a bottom-most nanostructure channel of the nanostructure transistor. This enables a back side source/drain contact to be connected to the recessed portion of the front side source/drain contact, and also enables the front side and back side source/drain contacts to share the same metal silicide layer.

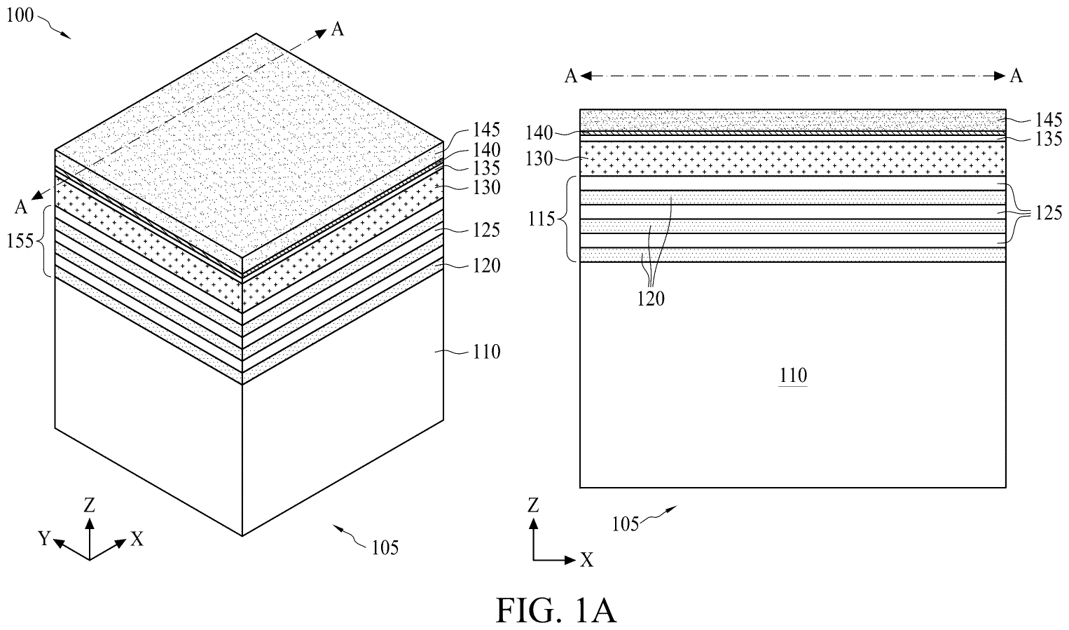

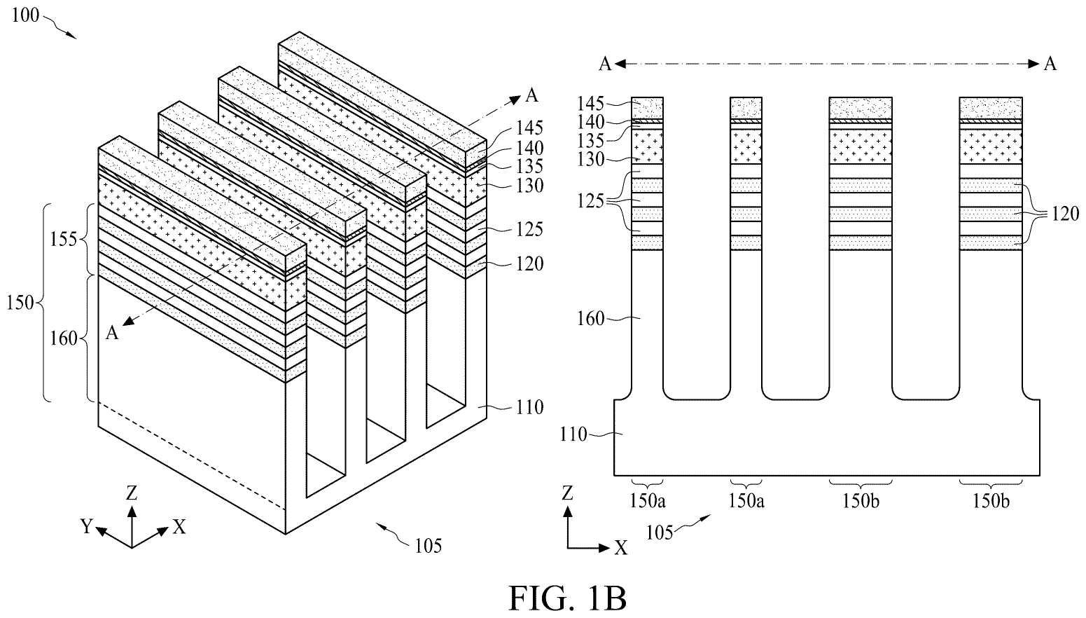

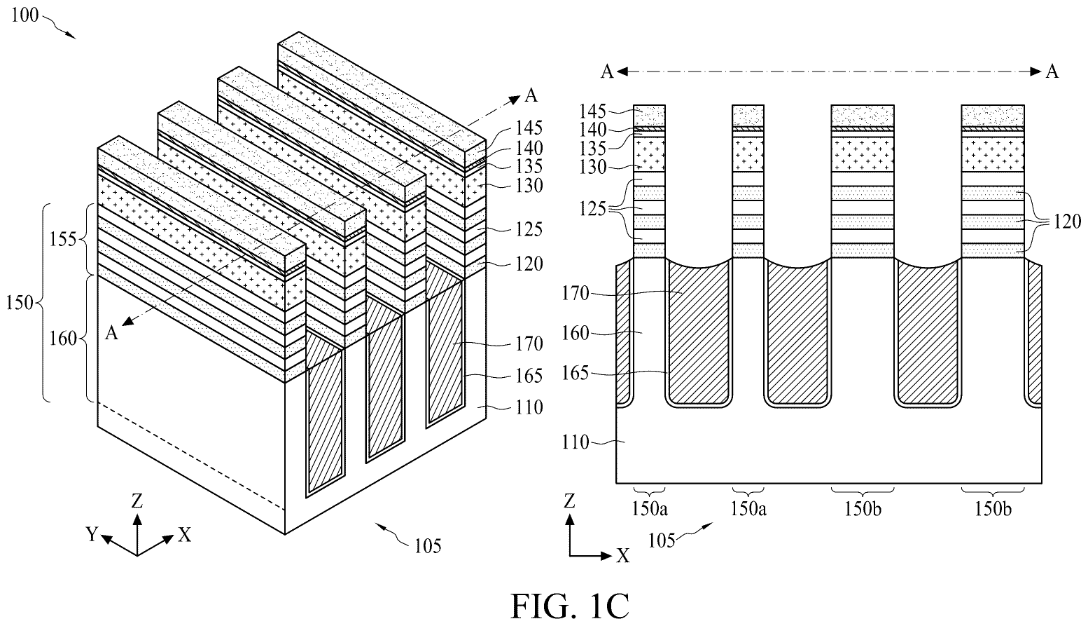

FIGS. 1A-1C are diagrams of an example implementation 100 of a fin definition process described herein. The example implementation 100 includes an example of forming fin structures and associated shallow trench isolation (STI) regions for a semiconductor device 105 described herein. The semiconductor device 105 may be manufactured to include one or more transistors. The one or more transistors may include nanostructure transistor(s) such as nanowire transistors, nanosheet transistors, gate-all-around (GAA) transistors, multi-bridge channel transistors, nanoribbon transistors, and/or other types of nanostructure transistors. The example implementation 100 includes an example of forming the fin structures and the associated STI regions for the transistors of the semiconductor device 105.

FIGS. 1A-1C each illustrate a perspective view of the semiconductor device 105 and a cross-sectional view along the line A-A in the perspective view. As shown in FIG. 1A, processing of the semiconductor device 105 is performed in connection with a semiconductor substrate 110. The semiconductor substrate 110 includes a silicon (Si) substrate, a substrate formed of a material including silicon, a III-V compound semiconductor material substrate such as gallium arsenide (GaAs), a silicon on insulator (SOI) substrate, a germanium (Ge) substrate, a silicon germanium (SiGe) substrate, a silicon carbide (SiC) substrate, or another type of semiconductor substrate.

A layer stack 115 is formed on the semiconductor substrate 110. The layer stack 115 may be referred to as a superlattice. The layer stack 115 includes a plurality of alternating layers that are arranged in a direction (e.g., the z-direction) that is approximately perpendicular to the semiconductor substrate 110. For example, the layer stack 115 includes vertically alternating layers of sacrificial nanostructure layers 120 and nanostructure channel layers 125 above the semiconductor substrate 110. The quantity of the sacrificial nanostructure layers 120 and the quantity of the nanostructure channel layers 125 illustrated in FIG. 1A are examples, and other quantities of the sacrificial nanostructure layers 120 and the nanostructure channel layers 125 are within the scope of the present disclosure.

The sacrificial nanostructure layers 120 enable a vertical distance to be defined between adjacent nanostructure channels that are formed from the nanostructure channel layers 125, and serve as placeholder layers for subsequently-formed gate structures of the transistors of the semiconductor device 105 that are formed around the nanostructure channels. The sacrificial nanostructure layers 120 include a first material composition, and the nanostructure channel layers 125 include a second material composition. In some implementations, the first material composition and the second material composition are the same material composition. In some implementations, the first material composition and the second material composition are different material compositions. As an example, the sacrificial nanostructure layers 120 may include silicon germanium (SiGe) and the nanostructure channel layers 125 may include silicon (Si). This enables the sacrificial nanostructure layers 120 and/or the nanostructure channel layers 125 to be selectively etched (e.g., enables the sacrificial nanostructure layers 120 and not the nanostructure channel layers 125 to be etched, enables the nanostructure channel layers 125 and not the sacrificial nanostructure layers 120 to be etched) depending on the type of etchant that is used.

One or more types of deposition tools may be used to deposit and/or grow the alternating layers of the layer stack 115 to include nanostructures (e.g., nanosheets) on the semiconductor substrate 110. For example, a deposition tool may be used to grow the sacrificial nanostructure layers 120 and/or the nanostructure channel layers 125 by epitaxial growth, which may include epitaxy techniques such as a molecular beam epitaxy (MBE), metalorganic chemical vapor deposition (MOCVD) process, and/or another suitable epitaxy technique.

Additionally and/or alternatively, the sacrificial nanostructure layers 120 and/or the nanostructure channel layers 125 may be deposited by chemical vapor deposition (CVD), physical vapor deposition (PVD), atomic layer deposition (ALD), and/or another suitable deposition technique.

One or more masking layers may be form (e.g., using one or more deposition tools) on the layer stack 115. The masking layer(s) may include a hard mask (HM) layer 130, a capping layer 135, an oxide layer 140, and/or a nitride layer 145. Masking layer(s) may be used to perform a fin patterning operation to form fin structures in the semiconductor substrate 110.

As shown in FIG. 1B, the layer stack 115 and the semiconductor substrate 110 are etched to remove portions of the layer stack 115 and portions of the semiconductor substrate 110. This results in formation of fin structures 150 that extend above the semiconductor substrate 110. The fin structures 150 may extend in a y-direction in the semiconductor device 105 and may be arranged in an x-direction in the semiconductor device 105. A fin structure 150 includes a portion 155 of the layer stack 115 over and/or on a fin portion 160 above the semiconductor substrate 110. The fin structures 150 may be formed by patterning the one or more masking layers and etching the semiconductor substrate 110 based on a pattern formed in one or more of the masking layers. The one or more masking layers may be patterned using photolithography techniques, including double-patterning or multi-patterning techniques. An etch tool may be used to etch the semiconductor substrate 110 based on the pattern using a dry etch technique (e.g., reactive ion etching), a wet etch technique, and/or a combination thereof.

As further shown in FIG. 1B, some fin structures 150 may be formed to have different widths for different types of nanostructure transistors. As an example, a first subset of fin structures 150a may be formed for p-type nanostructure transistors (e.g., p-type metal oxide semiconductor (PMOS) nanostructure transistors), and a second subset of fin structures 150b may be formed for n-type nanostructure transistors (e.g., n-type metal oxide semiconductor (NMOS) nanostructure transistors). As another example, a first subset of fin structures 150a may be formed for nanostructure transistors that are configured to operate at lower voltages, and a second subset of fin structures 150b may be formed for nanostructure transistors that are configured to operate at higher voltages.

As shown in FIG. 1C, a liner 165 and STI regions 170 are formed between adjacent fin portions 160 of the fin structures 150. The liner 165 and the STI regions 170 may each include a dielectric material such as a silicon oxide (SiOₓ), a silicon nitride (SiₓN_{y}), a silicon oxynitride (SiON), fluoride-doped silicate glass (FSG), a low-k dielectric material, and/or another suitable insulating material.

A deposition tool may be used to conformally deposit the liner (e.g., using ALD or another conformal deposition technique), and may deposit a dielectric layer (e.g., using CVD, PVD, a ALD, and/or another suitable deposition technique) on the liner 165 such that the dielectric layer fully fills in the spaces between the fin structures 150 and extends above the tops of the fin structures 150. A planarization tool may then be used to perform a planarization or polishing operation (e.g., a chemical mechanical planarization (CMP) operation) to planarize the dielectric layer such that the top surface of the dielectric layer is approximately co-planar with the top of the nitride layer 145. The nitride layer 145 functions as a CMP stop layer in the planarization operation. An etch tool may be used to then etch the dielectric layer to form the STI regions 170 such that the top surfaces of the STI region 170 are approximately co-planar with or below the bottom-most sacrificial nanostructure layer 120.

As indicated above, FIGS. 1A-1C are provided as an example. Other examples may differ from what is described with regard to FIGS. 1A-1C.

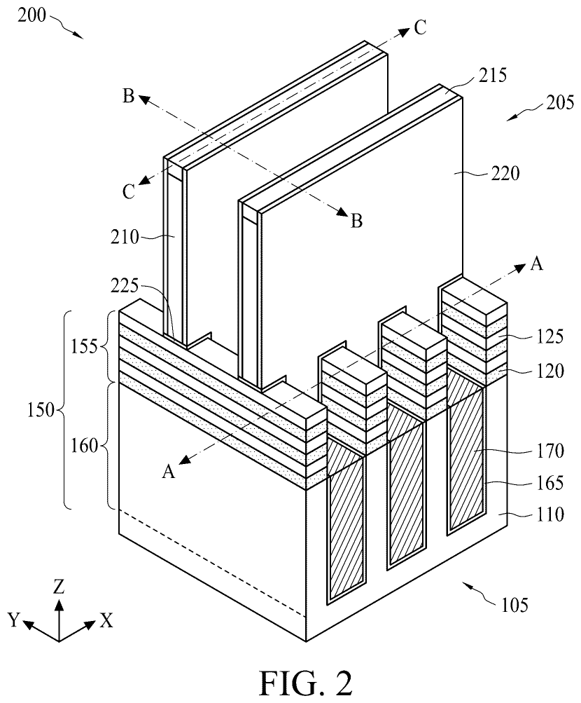

FIG. 2 is a diagram of an example implementation 200 of a dummy gate formation process described herein. The example implementation 200 includes an example of forming dummy gate structures 205 for nanostructure transistors of the semiconductor device 105. In some implementations, the operations described in connection with the example implementation 200 are performed after the processes described in connection with FIGS. 1A-1C.

FIG. 2 illustrates a perspective view of the semiconductor device 105 with the dummy gate structures 205 formed thereon. The dummy gate structures 205 (also referred to as dummy gate stacks or temporary gate structures) are formed over portions of the fin structures 150 and portions of the STI regions 170. The dummy gate structures 205 extend in the x-direction and are arranged in the y-direction such that the dummy gate structures 205 are approximately perpendicular to the fin structures 150. The dummy gate structures 205 are sacrificial structures that are to be replaced by replacement gate structures or replacement gate stacks at a subsequent processing stage for the semiconductor device 105. The dummy gate structures 205 may also be used to define source/drain (S/D) recesses in which source/drain regions of the nanostructure transistors are formed.

A dummy gate structure 205 may include a gate electrode layer 210, a hard mask layer 215 over and/or on the gate electrode layer 210, and spacer layers 220 on opposing sides of the gate electrode layer 210, and a gate dielectric layer 225 under the gate electrode layer 210. The gate electrode layer 210 includes polycrystalline silicon (polysilicon or PO) or another material. The hard mask layer 215 includes one or more layers such as an oxide layer (e.g., a pad oxide layer that may include silicon dioxide (SiO₂) or another material) and a nitride layer (e.g., a pad nitride layer that may include a silicon nitride such as Si₃N₄ or another material) formed over the oxide layer. The spacer layers 220 include a silicon oxycarbide (SiOC), a nitrogen free SiOC, or another suitable material. The gate dielectric layer 225 may include a silicon oxide (e.g., SiOₓ such as SiO₂), a silicon nitride (e.g., SiₓN_{y} such as Si₃N₄), a high dielectric constant (high-k) dielectric material (e.g., a dielectric material having a dielectric constant greater than approximately 3.9) and/or another suitable material.

The layers of the dummy gate structures 205 may be formed using various semiconductor processing techniques such as depositing the layers of the dummy gate structures 205, patterning the layers of the dummy gate structures 205 to define the dummy gate structures 205, and/or other semiconductor processing techniques.

FIG. 2 further illustrates reference cross-sections that are used in subsequent figures described herein. Cross-section A-A is in an x-z plane (referred to as a y-cut) across the fin structures 150 in the source/drain areas of the semiconductor device 105. Cross-section B-B is in a y-z plane (referred to as an x-cut) perpendicular to the cross-section A-A, and is across the dummy gate structures 205 and along an underlying fin structure 150. Cross-section C-C is in the x-z plane parallel to the cross-section A-A and perpendicular to the cross-section B-B, and is along a dummy gate structure 205. Subsequent figures refer to these reference cross-sections for clarity. In some figures, some reference numbers of components or features illustrated therein may be omitted to avoid obscuring other components or features for ease of depicting the figures.

As indicated above, FIG. 2 is provided as an example. Other examples may differ from what is described with regard to FIG. 2.

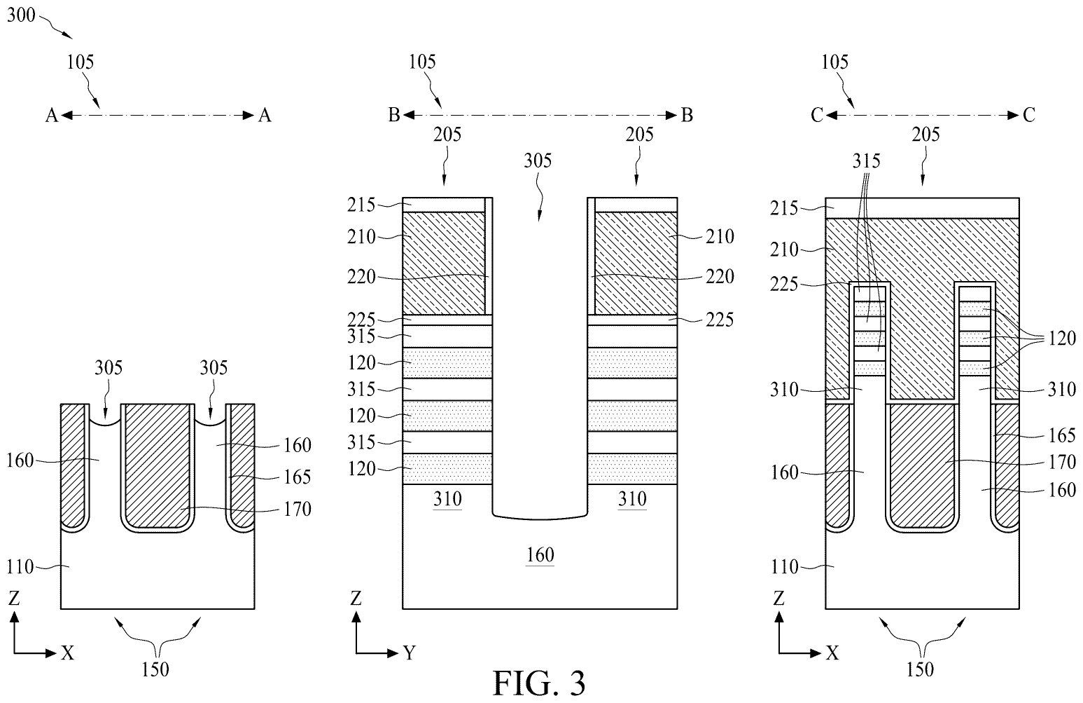

FIG. 3 is a diagrams of an example implementation 300 of a source/drain recess formation process described herein. The example implementation 300 includes an example of forming source/drain recesses 305 for source/drain regions of nanostructure transistors of the semiconductor device 105. FIG. 3 is illustrated from a plurality of perspectives illustrated in FIG. 2, including the perspective of the cross-sectional plane A-A in FIG. 2, the perspective of the cross-sectional plane B-B in FIG. 2, and the perspective of the cross-sectional plane C-C in FIG. 2. In some implementations, the operations described in connection with the example implementation 300 are performed after the processes described in connection with FIGS. 1A-2.

As shown in the cross-sectional plane A-A and cross-sectional plane B-B in FIG. 3, the source/drain recesses 305 are formed through portions 155 of a fin structure 150 in an etch operation. The source/drain recesses 305 are formed on opposing sides of a dummy gate structure 205. The etch operation may be performed using the etch tool and may be referred to a strained source/drain (SSD) etch operation. In some implementations, the etch operation includes the use of a plasma etch technique, a wet chemical etch technique, and/or another type of etch technique.

The source/drain recesses 305 also extend into a portion of the fin portion 160 of the fin structure 150. This results in formation of mesa regions 310 in the fin structure 150. The sidewalls of the portions of each source/drain recess 305 below the layer stack 115 correspond to sidewalls of mesa regions 310. A mesa region 310 (also referred to as pedestals) refers to a region of the fin portion 160 of the fin structure 150 on which nanostructure channels are defined from the nanostructure channel layers 125. The nanostructure channels 315 extend between adjacent source/drain recesses 305 and are located under the dummy gate structure 205 between the adjacent source/drain recesses 305.

The nanostructure channels 315 include silicon-based nanostructures (e.g., nanosheets or nanowires, among other examples) that function as the semiconductive channels of the nanostructure transistors of the semiconductor device 105. In some implementations, the nanostructure channels 315 may include silicon germanium (SiGe) or another silicon-based material. The nanostructure channels 315 are arranged in a direction (e.g., the z-direction) that is approximately perpendicular to the semiconductor substrate 110. In other words, the nanostructure channels 315 are vertically arranged or stacked above the semiconductor substrate 110.

As indicated above, FIG. 3 is provided as an example. Other examples may differ from what is described with regard to FIG. 3.

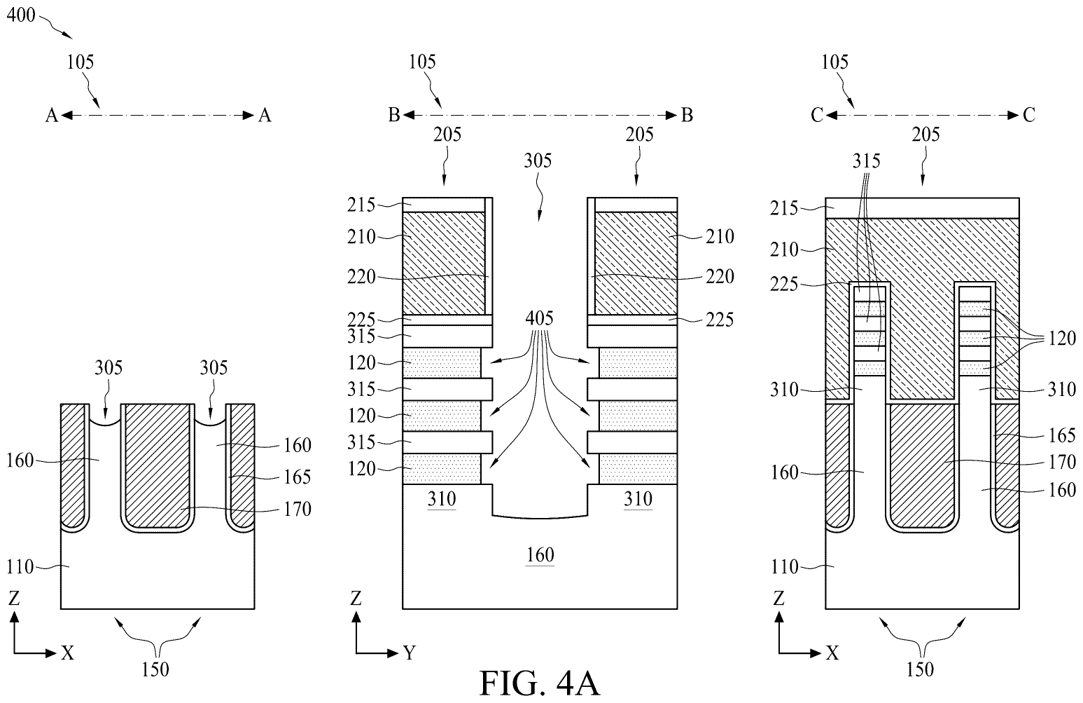

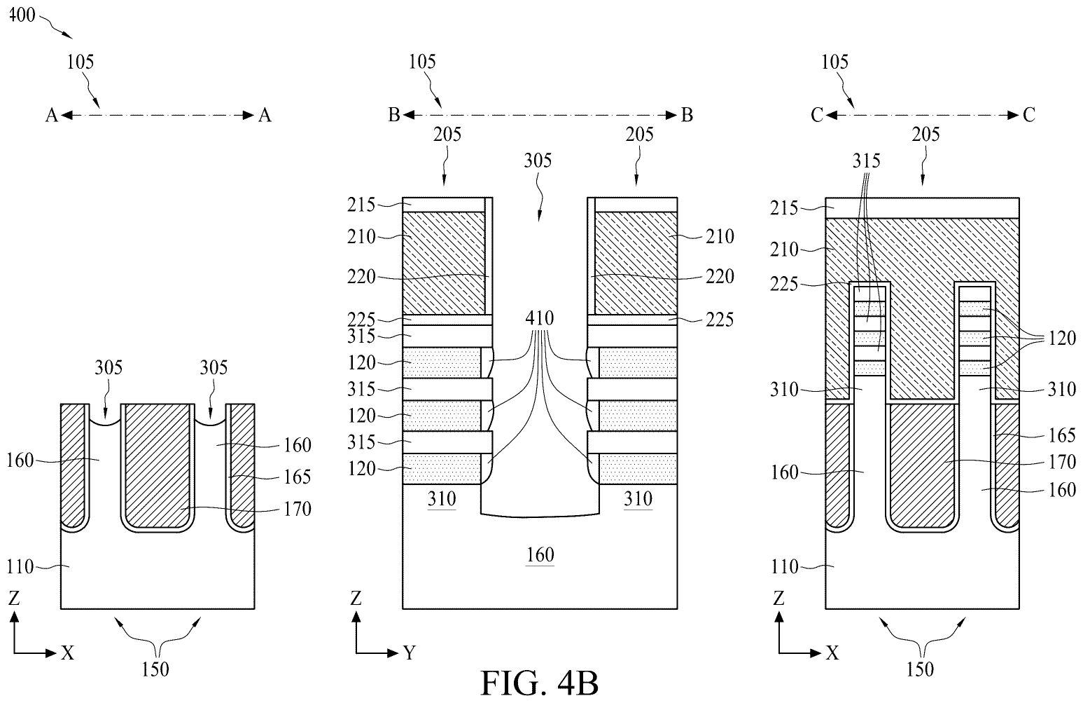

FIGS. 4A and 4B are diagrams of an example implementation 400 of an inner spacer formation process described herein. The example implementation 400 includes an example of forming inner spacers between ends of the nanostructure channels 315 that are exposed in the source/drain recesses 305. FIGS. 4A and 4B are illustrated from a plurality of perspectives illustrated in FIG. 2, including the perspective of the cross-sectional plane A-A in FIG. 2, the perspective of the cross-sectional plane B-B in FIG. 2, and the perspective of the cross-sectional plane C-C in FIG. 2. In some implementations, the operations described in connection with the example implementation 400 are performed after the processes described in connection with FIGS. 1A-3.

As shown in the cross-sectional plane A-A and in the cross-sectional plane B-B in FIG. 4A, the ends of the sacrificial nanostructure layers 120 may be laterally etched (e.g., in the x-direction that is approximately parallel to a length of the sacrificial nanostructure layers 120) in an etch operation, thereby forming cavities 405 between the ends of the nanostructure channels 315 that are exposed in the source/drain recesses 305. An etch tool may be used to perform a wet etch operation to selectively etch the ends of the sacrificial nanostructure layers 120 relative to the nanostructure channels 315 to form the cavities 405. Additionally and/or alternatively, another etch technique may be used, such as dry etching (e.g., gas-based etching).

As shown in the cross-sectional plane A-A and in the cross-sectional plane B-B in FIG. 4B, inner spacers (InSP) 410 are formed in the cavities 405 in the ends of the sacrificial nanostructure layers 120 that are exposed in the source/drain recesses 305. The inner spacers 410 may be included to reduce parasitic capacitance in the nanostructure transistors and to protect source/drain regions (that are subsequently formed in the source/drain recesses 305) from being etched in a nanosheet release operation to remove the sacrificial nanostructure layers 120 between the nanostructure channels 315. The inner spacers 410 include a silicon nitride (SiₓN_{y}), a silicon oxide (SiOₓ), a silicon oxynitride (SiON), a silicon oxycarbide (SiOC), a silicon carbon nitride (SiCN), a silicon oxycarbonnitride (SiOCN), and/or another dielectric material.

To form the inner spacers 410, a deposition tool may be used to deposit a layer of dielectric material in the cavities 405 and along the sidewalls and bottom surface of the source/drain recesses 305. A CVD technique, a PVD technique, and ALD technique, and/or another deposition technique may be used to deposit the layer of dielectric material. An etch tool is used to subsequently remove excess material of the layer of dielectric material from the source/drain recesses such that remaining portions correspond to the inner spacers 410. Alternatively, the inner spacers 410 may be selectively formed on the ends of the sacrificial nanostructure layers 120 using precursors that selectively bond to the material of the sacrificial nanostructure layers 120 and not to the material of the fin portion 160 and the nanostructure channels 315.

As indicated above, FIGS. 4A and 4B are provided as an example. Other examples may differ from what is described with regard to FIGS. 4A and 4B.

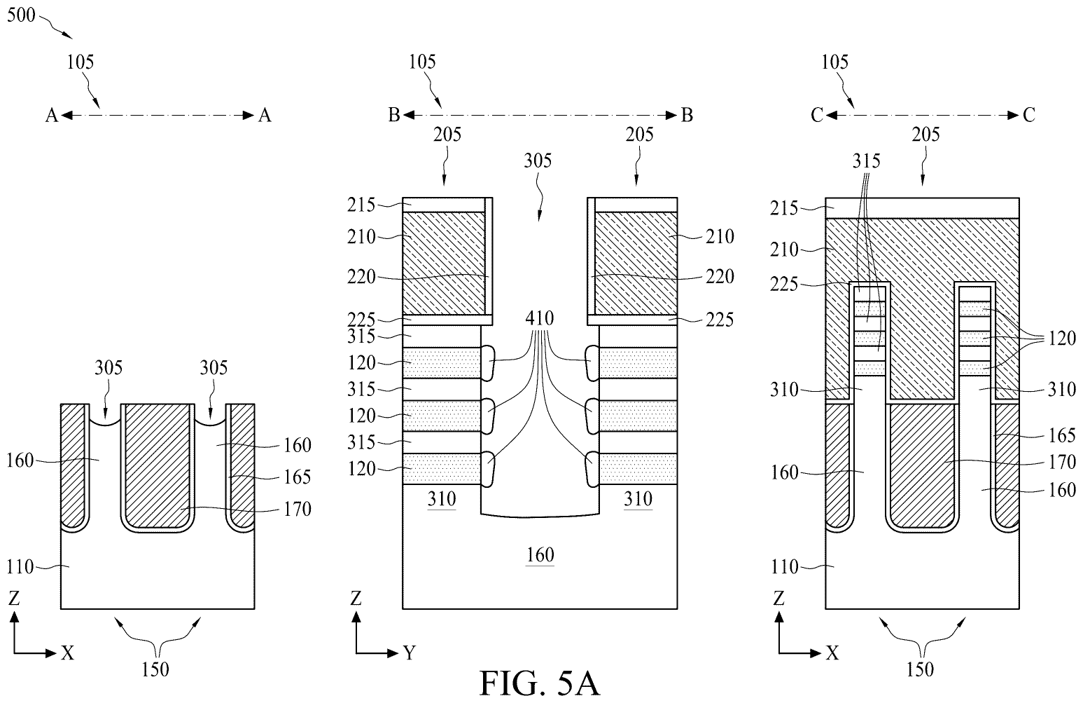

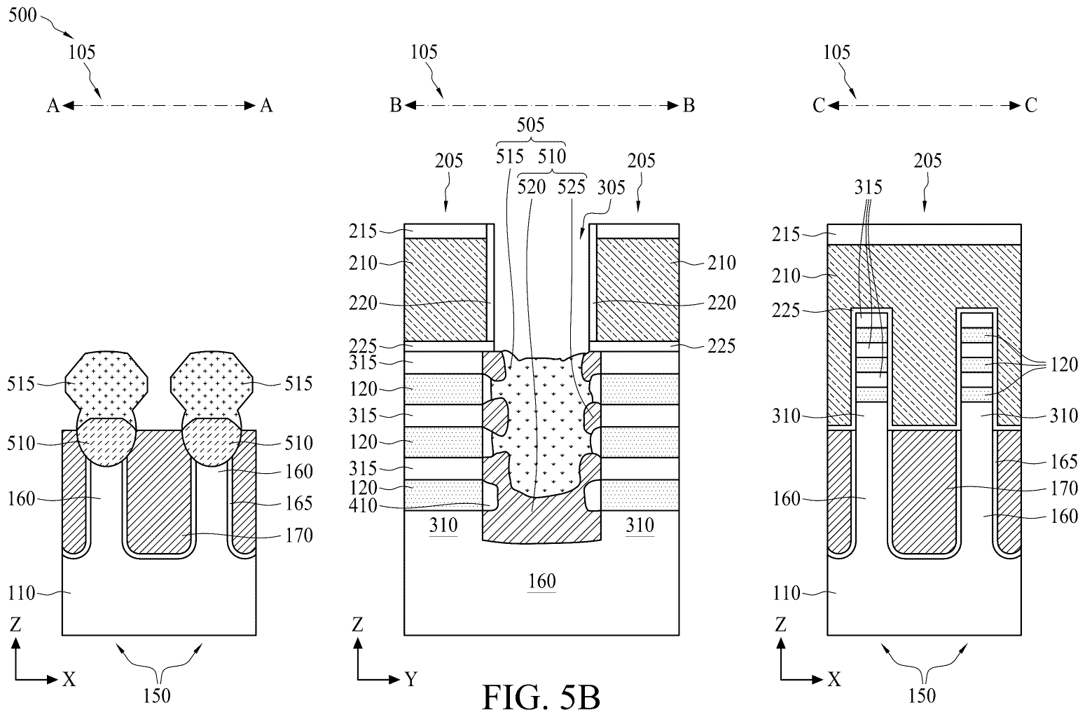

FIGS. 5A and 5B are diagrams of an example implementation 500 of a source/drain region formation process described herein. The example implementation 500 includes an example of forming the source/drain regions of the nanostructure transistors of the semiconductor device 105. FIGS. 5A and 5B are illustrated from a plurality of perspectives illustrated in FIG. 2, including the perspective of the cross-sectional plane A-A in FIG. 2, the perspective of the cross-sectional plane B-B in FIG. 2, and the perspective of the cross-sectional plane C-C in FIG. 2. In some implementations, the operations described in connection with the example implementation 500 are performed after the processes described in connection with FIGS. 1A-4B.

As shown in the cross-sectional plane A-A and in the cross-sectional plane B-B in FIG. 5A, the ends of the nanostructure channels 315 may be laterally etched (e.g., in the x-direction that is approximately parallel to a length of the sacrificial nanostructure layers 120) in an etch operation, thereby forming recesses between vertically adjacent inner spacers 410. This may be referred to as a channel push operation. An etch tool may be used to perform a wet etch operation to selectively etch the ends of the nanostructure channels 315 relative to the sacrificial nanostructure layers to form the cavities 505. Additionally and/or alternatively, another etch technique may be used, such as dry etching (e.g., gas-based etching).

As shown in the cross-sectional plane A-A and the cross-sectional plane B-B in FIG. 5B, the source/drain recess 305 is filled with one or more layers to form a source/drain region 505 in the source/drain recess 305. For example, a deposition tool may be used to deposit a first epitaxial layer 510 (sometimes referred to as an “L1”) at the bottom of the source/drain recess 305 and on recessed ends of the nanostructure channels 315. As another example, a deposition tool may deposit a second epitaxial layer 515 (sometimes referred to as an “L2”) in the source/drain recess 305. The second epitaxial layer 515 may fill in the remaining area in the source/drain recess 305 below the dummy gate structures 205 and may be in contact with the first epitaxial layer 510 and the inner spacers 410 that are still exposed in the source/drain recess 305.

“Source/drain region” may refer to a source or a drain, individually or collectively, depending upon the context. Source/drain regions 505 may be included on opposing sides of a dummy gate structure 205 such that the nanostructure channels 315 under the dummy gate structure 205 extend between, and are electrically coupled to, source/drain regions 505.

The first epitaxial layer 510 and the second epitaxial layer 515 of a source/drain region 505 may each include a semiconductor material such as silicon (Si), silicon germanium (SiGe), silicon arsenide (SiAs), silicon phosphorous (SiP), and/or another semiconductor material. The first epitaxial layer 510 and the second epitaxial layer 515 may each be doped with one or more types of dopants such as arsenic (As), phosphorous (P), and/or boron (B), among other examples.

For a p-type metal-oxide semiconductor (PMOS) nanostructure transistor, the first epitaxial layer 510 and the second epitaxial layer 515 of a source/drain region 505 may each include silicon germanium (SiGe) doped with boron (B). The germanium (Ge) concentration of the second epitaxial layer 515 may be greater than the germanium (Ge) concentration of the first epitaxial layer 510. For example, the germanium (Ge) concentration of the second epitaxial layer 515 may be included in a range of approximately 40% to approximately 60%, whereas the germanium (Ge) concentration of the first epitaxial layer 510 may be included in a range of approximately 10% to approximately 20%. However, other values and ranges are within the scope of the present disclosure. The boron (B) dopant concentration of the second epitaxial layer 515 and the boron (B) dopant concentration of the first epitaxial layer 510 may each be included in a range of approximately 5×10²⁰ to approximately 5×10²¹. However, other values and ranges are within the scope of the present disclosure.

For an n-type metal-oxide semiconductor (NMOS) nanostructure transistor, the first epitaxial layer 510 and the second epitaxial layer 515 of a source/drain region 505 may each include silicon (Si) doped with arsenic (As) and/or phosphorous (P), among other examples. The dopant concentration of the second epitaxial layer 515 may be greater than the dopant concentration of the first epitaxial layer 510. For example, the dopant concentration of the second epitaxial layer 515 may be included in a range of approximately 2×10²¹ to approximately 9×10²¹, whereas the dopant concentration of the first epitaxial layer 510 may be included in a range of approximately 1×10²⁰ to approximately 1×10²¹. However, other values and ranges are within the scope of the present disclosure.

The first epitaxial layer 510 and the second epitaxial layer 515 of a source/drain region 505 may each be epitaxially grown, deposited (e.g., using CVD, PVD, ALD), and/or formed using one or more other deposition techniques. For example, a deposition tool may epitaxially a grow merged region 520 of the first epitaxial layer 510 at the bottom of the source/drain recess 305. The merged region 520 may include a continuous layer of epitaxially-grown material that spans from the mesa regions 310 up to the ends of a bottom-most nanostructure channel 315.

As another example, a deposition tool may epitaxially grow a plurality of non-contiguous second epitaxial regions 525 of the first epitaxial layer 510 in the recesses in the ends of nanostructure channels 315 above the merged region 520. The non-contiguous second epitaxial regions 525 are regions of epitaxially-grown material that are not in contact with each other (e.g., because of being separated by the inner spacers 410), and that are not in contact with the merged region 520. The second epitaxial layer 515 may grow on portions of the inner spacers 410 that are exposed between the non-contiguous second epitaxial regions 525, and between the merged region 520 and the non-contiguous second epitaxial regions 525.

As indicated above, FIGS. 5A and 5B are provided as an example. Other examples may differ from what is described with regard to FIGS. 5A and 5B.

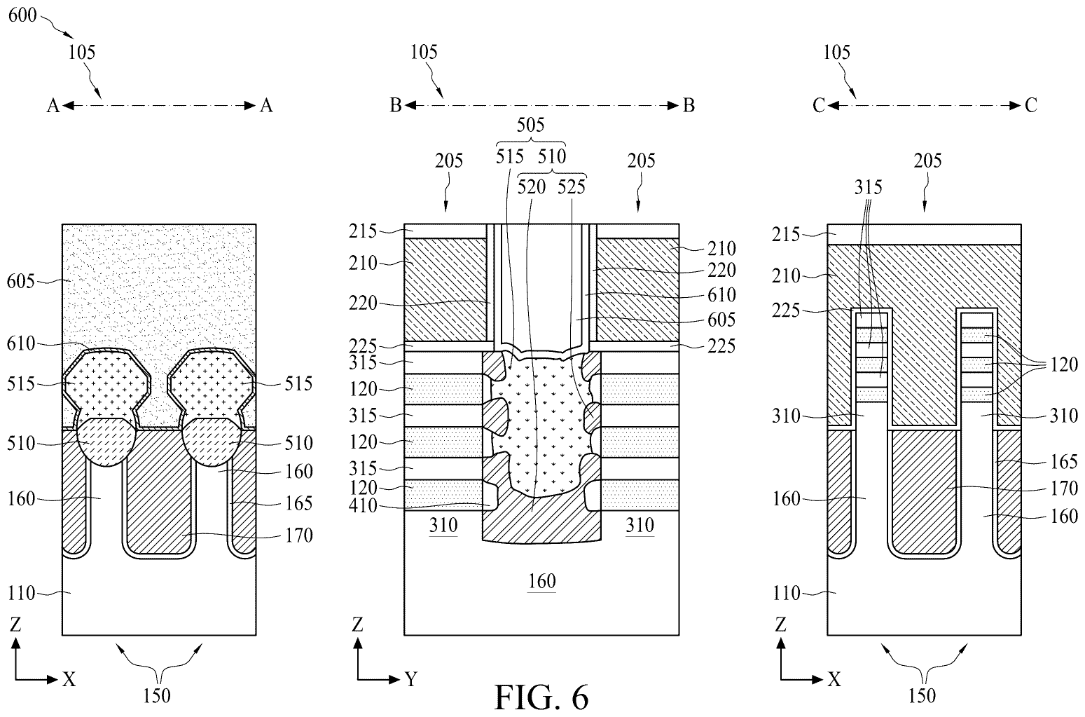

FIG. 6 is a diagram of an example implementation 600 of an interlayer dielectric (ILD) formation process described herein. FIG. 6 is illustrated from a plurality of perspectives illustrated in FIG. 2, including the perspective of the cross-sectional plane A-A in FIG. 2, the perspective of the cross-sectional plane B-B in FIG. 2, and the perspective of the cross-sectional plane C-C in FIG. 2. In some implementations, the operations described in connection with the example implementation 600 are performed after the processes described in connection with FIGS. 1A-5B.

As shown in the cross-sectional plane A-A and the cross-sectional plane B-B in FIG. 6, a dielectric layer 605 is formed over the source/drain regions 505. The dielectric layer 605 (which may be referred to as an ILD layer) fills in areas between the dummy gate structures 205. The dielectric layer 605 is formed to reduce the likelihood of, and/or prevent, damage to the source/drain regions 505 during a replacement gate process to replace the dummy gate structures 205. The dielectric layer 605 may be referred to as an ILD zero (ILDO) layer or another ILD layer.

In some implementations, a contact etch stop layer (CESL) 610 is conformally deposited (e.g., by a deposition tool) over the source/drain regions 505 prior to formation of the dielectric layer 605. The dielectric layer 605 is then formed on the CESL 610. The CESL 610 may provide a mechanism to stop an etch process when forming contacts or vias for the source/drain regions 505.

The dielectric layer 605 may include an oxide (e.g., a silicon oxide (SiOₓ) and/or another oxide material), an undoped silicate glass (USG), a boron-containing silicate glass (BSG), a fluorine-containing silicate glass (FSG), tetraethyl orthosilicate (TEOS), hydrogen silsesquioxane (HSQ), and/or another suitable dielectric material. In some implementations, the dielectric layer 605 includes an extreme low dielectric constant (ELK) dielectric material having a dielectric constant that is less than approximately 2.5. Examples of ELK dielectric materials include carbon doped silicon oxide (C—SiOₓ), amorphous fluorinated carbon (α-CₓF_{y}), parylene, bis-benzocyclobutenes (BCB), polytetrafluoroethylene (PTFE), a silicon oxycarbide (SiOC) polymer, porous hydrogen silsesquioxane (HSQ), porous methyl silsesquioxane (MSQ), porous polyarylether (PAE), and/or porous silicon oxide (SiOₓ), among other examples. The dielectric layer 605 may be deposited using a deposition process, such as ALD, CVD, or another deposition technique.

The CESL 610 may be formed of a dielectric material having a different etch selectivity from adjacent layers or components. The CESL 610 may include or may be a nitrogen-containing material, a silicon-containing material, and/or a carbon-containing material.

Furthermore, the CESL 610 may include or may be silicon nitride (SiₓN_{y}), silicon carbon nitride (SiCN), carbon nitride (CN), silicon oxynitride (SiON), silicon carbon oxide (SiCO), or a combination thereof, among other examples. The CESL 610 may be deposited using a deposition process, such as ALD, CVD, or another deposition technique.

As indicated above, FIG. 6 is provided as an example. Other examples may differ from what is described with regard to FIG. 6.

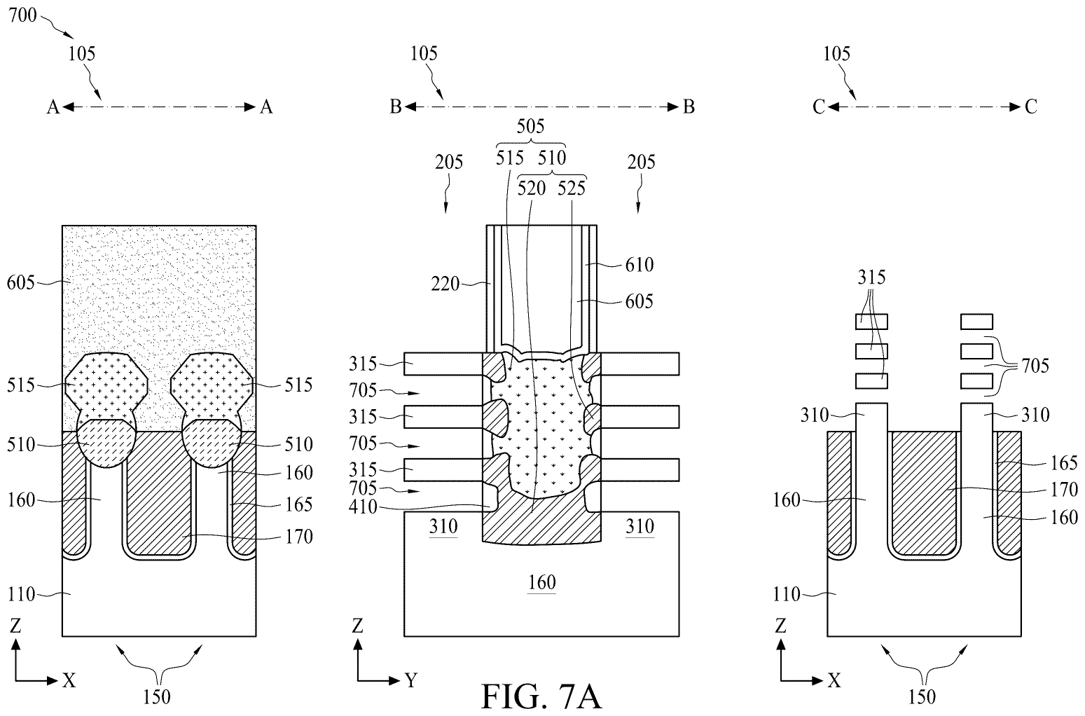

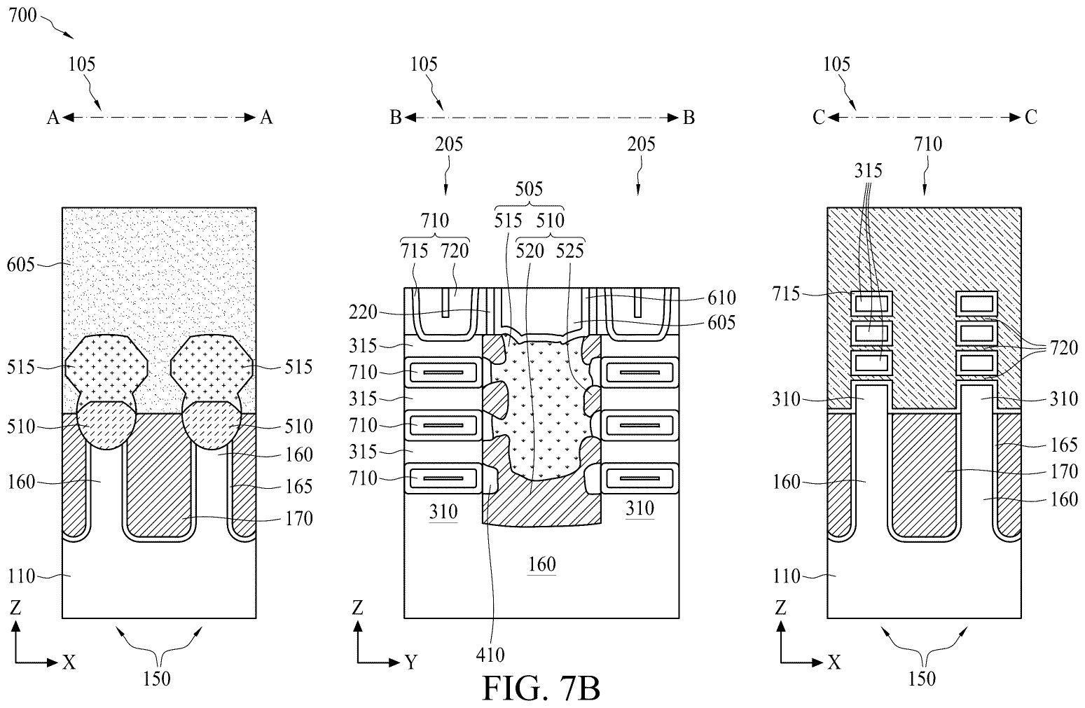

FIGS. 7A and 7B are diagrams of an example implementation 700 of a replacement gate (RPG) process described herein. The example implementation 700 includes an example of a replacement gate process for replacing the dummy gate structures 205 with high-k/metal gate structures (e.g., the replacement gate structures) for the nanostructure transistors of the semiconductor device 105. FIGS. 7A and 7B are each illustrated from a plurality of perspectives illustrated in FIG. 2, including the perspective of the cross-sectional plane A-A in FIG. 2, the perspective of the cross-sectional plane B-B in FIG. 2, and the perspective of the cross-sectional plane C-C in FIG. 2. In some implementations, the operations described in connection with the example implementation 700 are performed after the operations described in connection with FIGS. 1A-6.

As shown in the cross-sectional plane B-B and the cross-sectional plane C-C in FIG. 7A, the replacement gate process includes a dummy gate removal operation. The dummy gate removal operation includes removing the dummy gate structures 205 from the semiconductor device 105. The removal of the dummy gate structures 205 leaves behind openings (or recesses) in the dielectric layer 605, and provides access to the underlying sacrificial nanostructure layers 120. The dummy gate structures 205 may be removed in one or more etch operations. Such etch operations may include a plasma etch technique, a wet chemical etch technique, and/or another type of etch technique.

As further shown FIG. 7A, the replacement gate process includes a nanostructure release operation (e.g., an SiGe release operation). The nanostructure release operation is performed to remove the sacrificial nanostructure layers 120 (e.g., the silicon germanium layers). This results in openings 705 between the nanostructures channels 315 (e.g., the areas around the nanostructure channels 315). The sacrificial nanostructure layers 120 may be removed through the spaces that were previously occupied by the dummy gate structures 205. The nanostructure release operation may include the use of an etch tool to perform an etch operation to remove the sacrificial nanostructure layers 120 based on a difference in etch selectivity between the material of the sacrificial nanostructure layers 120 and the material of the nanostructure channels 315, and between the material of the sacrificial nanostructure layers 120 and the material of the inner spacers 410. The inner spacers 410 may function as etch stop layers in the etch operation to protect the source/drain regions 505 from being etched.

As shown in the cross-sectional plane B-B and the cross-sectional plane C-C in FIG. 7B, the replacement gate operation includes forming gate structures (e.g., replacement gate structures) 710 in the openings 705 between the source/drain regions 505 and between the inner spacers 410. In particular, the gate structures 710 fill the areas between and around the nanostructure channels 315 that were previously occupied by the sacrificial nanostructure layers 120 such that the gate structures 710 fully wrap around the nanostructure channels 315 and surround the nanostructure channels 315. This increases control of the nanostructure channel 315, increases drive current for the nanostructure transistor(s) of the semiconductor device 105, and/or reduces short channel effects (SCEs) for the nanostructure transistor(s) of the semiconductor device 105, among other examples. The gate structures 710 may also fill in the spaces that were previously occupied by the dummy gate structures 205. Portions of a gate structure 710 are formed in between pairs of nanostructure channels 315 in an alternating vertical arrangement. In other words, the semiconductor device 105 includes one or more vertical stacks of alternating nanostructure channels 315 and portions of a gate structure 710, as shown in FIG. 7B.

The gate structures 710 may each include a gate dielectric layer 715 and a metal gate electrode 720. A metal gate electrode 720 may include one or more metal materials such as tungsten (W), cobalt (Co), ruthenium (Ru), and/or titanium (Ti), among other examples. Additionally and/or alternatively, the gate structures 710 may each include one or more work function metal layers for tuning the work function of the metal gate electrode 720.

A gate dielectric layer 715 may be a conformal high-k dielectric liners that is deposited onto the nanostructure channels 315 and on sidewalls of the inner spacers 410 prior to formation of a gate electrode 720. The gate structures 710 may each include additional layers such as an interfacial layer, an adhesion layer, and/or a capping layer, among other examples. The gate dielectric layer 715 may include one or more high-k dielectric materials, such as a silicon nitride (SiₓN_{y}), a hafnium oxide (HfOₓ), a lanthanum oxide (LaOₓ), and/or another suitable high-k dielectric material.

Some source/drain regions 505 and gate structures 710 may be shared between two or more nanoscale transistors of the semiconductor device 105. In these implementations, one or more source/drain regions 505 and a gate structure 710 may be connected or coupled to a plurality of nanostructure channels 315, as shown in the example in FIG. 7B. This enables the plurality of nanostructure channels 315 to be controlled by a single gate structure 710 and a pair of source/drain regions 505.

As indicated above, FIGS. 7A and 7B are provided as an example. Other examples may differ from what is described with regard to FIGS. 7A and 7B.

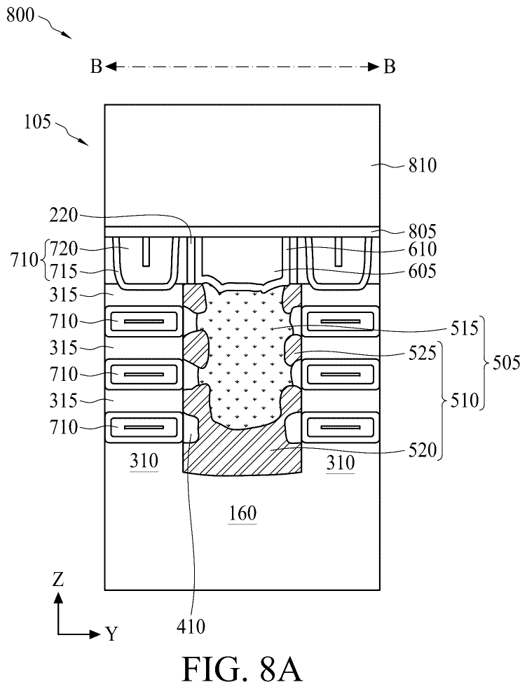

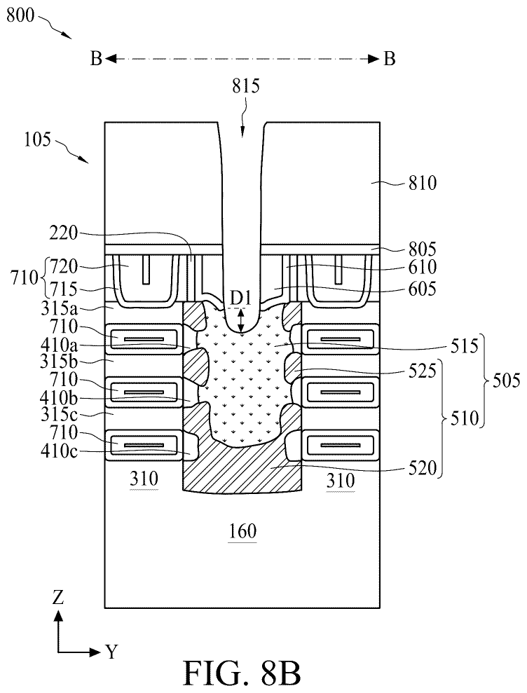

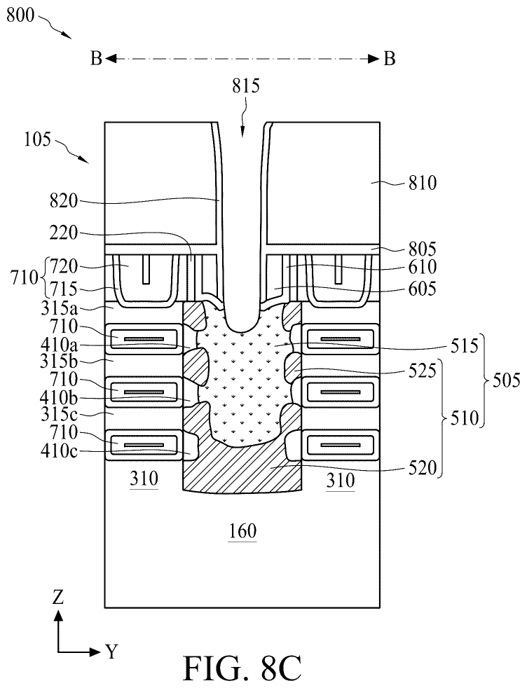

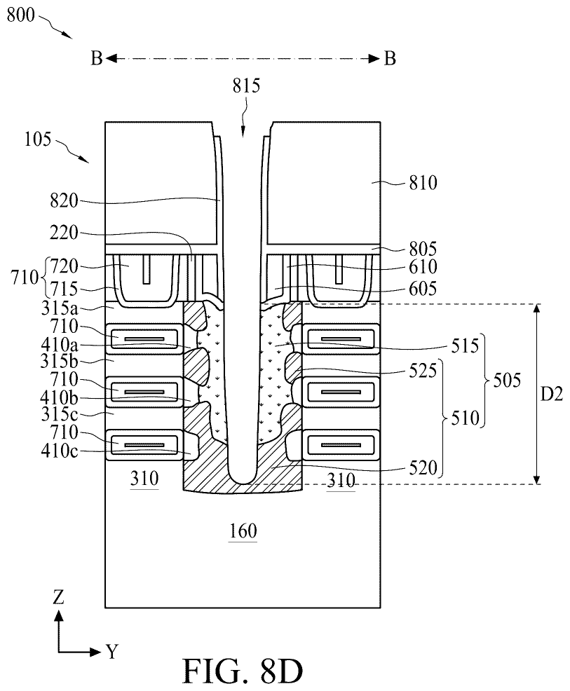

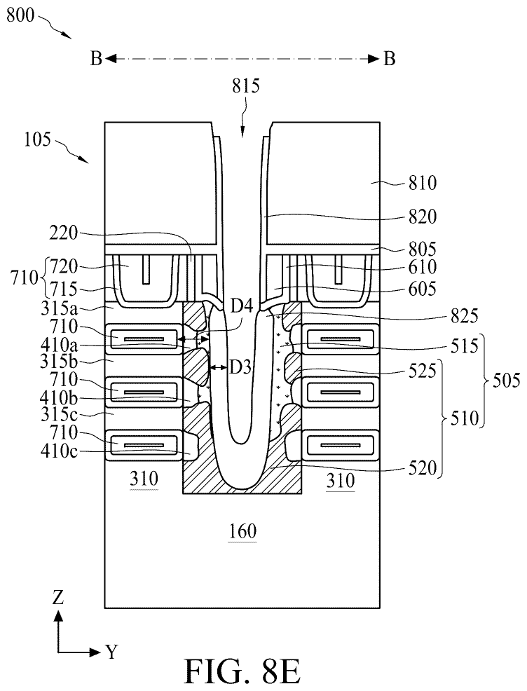

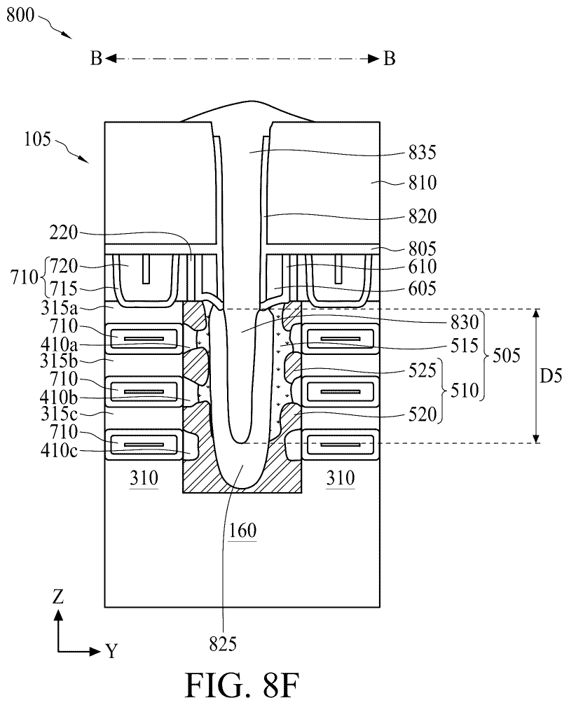

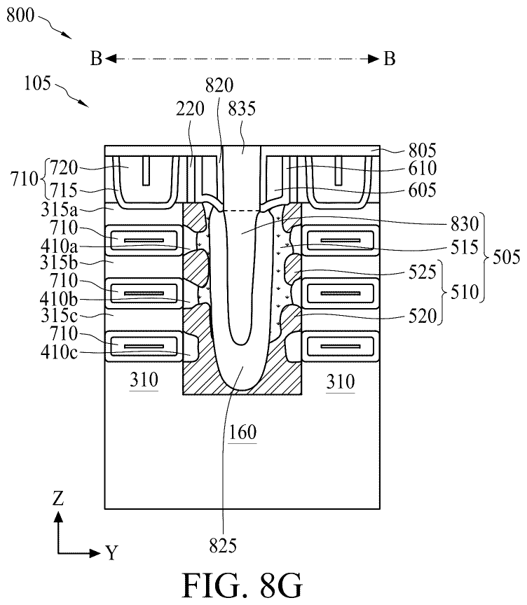

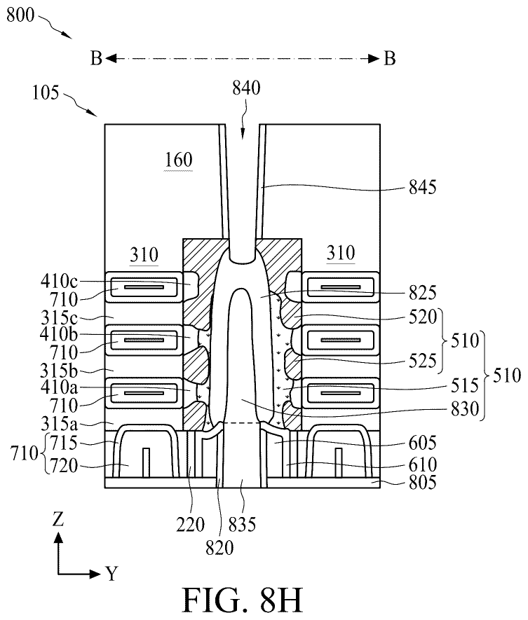

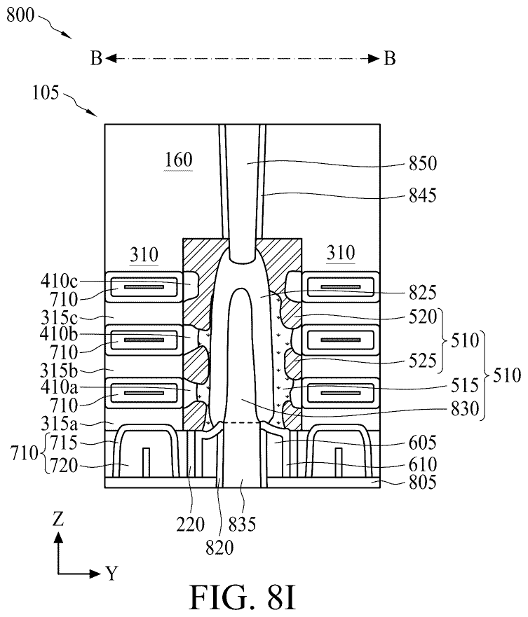

FIGS. 8A-8I are diagrams of an example implementation 800 of a source/drain contact formation process described herein. In particular, the example implementation 800 includes an example of forming front side and back side source/drain contacts. The front side source/drain contact is formed such that the front side source/drain contact is recessed within a source/drain region 505 of a nanostructure transistor of the semiconductor device 105 from a first side (e.g., a front side) of the semiconductor device 105. The back side source/drain contact formed such that the back side source/drain contact is connected to the source/drain region from a second side (e.g., a back side) of the semiconductor device 105 opposing the first side in the z-direction. This enables a lower contact resistance and lower current crowding to be achieved between the source/drain region 505 and the front side and back side source/drain contacts. Moreover, this enables the front side and back side source/drain contacts to share the same metal silicide layer, which reduces the process complexity for forming the nanostructure transistor.

FIGS. 8A-8I are each illustrated from the perspective of the cross-sectional plane B-B in FIG. 2. In some implementations, the operations described in connection with the example implementation 800 are performed after the operations described in connection with FIGS. 1A-7B.

As shown in FIG. 8A, an etch stop layer (ESL) 805 may be formed above and/or on the dielectric layer 605, and above and/or on the top portions of the gate structures 710. Another dielectric layer 810 may be formed over and/or on the ESL 805.

The ESL 805 may include one or more dielectric materials, such as a silicon nitride (SixNy), silicon carbon nitride (SiCN), carbon nitride (CN), silicon oxynitride (SiON), silicon carbon oxide (SiCO), or a combination thereof, among other examples. The dielectric layer 810 may be referred to as an ILD layer (e.g., an ILD1 layer), and may include one or more dielectric materials such as an oxide (e.g., a silicon oxide (SiOₓ) and/or another oxide material), an undoped silicate glass (USG), a boron-containing silicate glass (BSG), a fluorine-containing silicate glass (FSG), tetraethyl orthosilicate (TEOS), hydrogen silsesquioxane (HSQ), and/or another suitable dielectric material. In some implementations, the dielectric layer 810 includes an ELK dielectric material.

A deposition tool may be used to deposit the ESL 805 and/or the dielectric layer 810 using a PVD technique, an ALD technique, a CVD technique, and/or another suitable deposition technique. The ESL 805 and/or the dielectric layer 810 may be deposited in one or more deposition operations. In some implementations, a planarization tool may be used to perform a planarization operation (e.g., a CMP operation) to planarize the ESL 805 and/or the dielectric layer 810 after the ESL 805 and/or the dielectric layer 810 is deposited.

As shown in FIG. 8B, a contact recess 815 is formed through the dielectric layer 810, through the ESL 805, through the dielectric layer 605, and into the source/drain region 505. The contact recess 815 may be referred to as a front side contact recess in that the contact recess 815 is formed from and into a front side of the semiconductor device 105. “Front side” of the semiconductor device 105 may refer to a side of the semiconductor substrate 110 above which the layer stack 115 of the sacrificial nanostructure layers 120 and the nanostructure channel layers 125 were formed. The fin portions 160 may extend structures above the front side of the semiconductor substrate 110.

A first etch operation using an etch tool is performed to form the contact recess 815 to a first depth (indicated in FIG. 8B as dimension D1) relative to a top of the source/drain region 505. The contact recess 815 may extend into the second epitaxial layer 515 of the source/drain region 505.

In some implementations, a pattern in a photoresist layer is used to form the contact recess 815. In these implementations, a deposition tool may be used to form the photoresist layer on the dielectric layer 810 (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern. An etch tool may be used to etch the dielectric layer 810, the ESL 805, the dielectric layer 605, and/or the second epitaxial layer 515 of the source/drain region 505 based on the pattern to form the contact recess 815. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for forming the contact recess 815 on a pattern.

In some implementations, the first depth (the dimension D1) to which the contact recess 815 extends into the source/drain region 505 after the first etch operation may be included in a range of approximately 1 nanometer to approximately 9 nanometers. However, other values and ranges are within the scope of the present disclosure.

As shown in FIG. 8C, sidewall liners 820 may be formed on portions of the sidewalls of the contact recess 815 above the source/drain region 505. The sidewall liners 820 may be formed as protective liners that protect the sidewalls of the contact recess 815 from being etched (and therefore, the lateral width of the contact recess 815 widened) during a second etch operation that is to be subsequently performed to increase the depth of the contact recess 815.

Additionally and/or alternatively, the sidewall liners 820 may include barrier liners that are included to reduce and/or prevent diffusion of material from a source/drain contact (e.g., that is to be formed in the contact recess 815) into the surrounding dielectric layers.

The sidewall liners 820 may include one or more dielectric materials. For example, the sidewall liners 820 may include a silicon nitride (SiₓN_{y} such as Si₃N₄), a silicon oxynitride (SiON), a silicon oxycarbide (SiOC), a silicon oxycarbonitride (SiOCN), and/or another suitable dielectric material. The material of the sidewall liners 820 may be different than the material of the source/drain region 505 (e.g., than the semiconductor material of the second epitaxial layer 515) to provide etch selectivity between the sidewall liners 820 and the source/drain region 505. This enables the source/drain region 505 to be further etched in the second etch operation to increase the depth of the contact recess 815 with minimal to no consumption of the sidewall liners 820.

To form the sidewall liners 820, a conformal layer of dielectric material may be deposited on the sidewalls of the contact recess 815 (e.g., corresponding to exposed surfaces of the dielectric layer 605, exposed surfaces of the ESL 805, and exposed surfaces of the dielectric layer 810) and on the bottom surface of the contact recess 815 (e.g., corresponding to the exposed surfaces of the second epitaxial layer 515 of the source/drain region 505). A deposition tool may be used to deposit the conformal layer of dielectric material using a deposition technique such as ALD and/or CVD, among other examples.

An etch tool may be used to trim the portion of the conformal layer of dielectric material located on the bottom surface of the contact recess 815 so that the conformal layer of dielectric material is removed from the surface of the second epitaxial layer 515 of the source/drain region 505. In this way, the surface of the second epitaxial layer 515 of the source/drain region 505 is exposed again through the contact recess 815, and the remaining portions of the conformal layer of dielectric material located on the sidewalls of the contact recess 815 correspond to the sidewall liners 820.

An anisotropic etch technique may be used to trim the portion of the conformal layer of dielectric material located on the bottom surface of the contact recess 815 so that the portions of the conformal layer of dielectric material located on the sidewalls of the contact recess 815 remain as the sidewall liners 820. For example, a plasma-based etch technique (such as a reactive ion etch (RIE) technique) may be used to perform a primarily vertical (e.g., z-direction) etch to trim the conformal layer of dielectric material. However, other etch techniques are within the scope of the present disclosure.

As shown in FIG. 8D, a second etch operation is performed (e.g., after the first etch operation described in connection with FIG. 8B) to increase the depth of the contact recess 815 in the source/drain region 505 from the first depth (dimension D1) to a second depth (indicated in FIG. 8D as a dimension D2) that is greater than the first depth. In this way, the contact recess 815 extends through the second epitaxial layer 515 and into the merged region 520 of the first epitaxial layer 510 at the bottom of the source/drain region 505 after the second etch operation.

For example, after the first etch operation described in connection with FIG. 8B, the contact recess 815 may extend to a depth of top-most nanostructure channels (e.g., nanostructure channels 315a in vertical stacks of nanostructure channels 315a-315c). After the second operation described in connection with FIG. 8D, the contact recess 815 may extend to a depth of the mesa regions 310 under bottom-most nanostructure channels (e.g., nanostructure channels 315c in the vertical stacks of nanostructure channels 315a-315c).

In some implementations, the second depth is included in a range of approximately 10 nanometers to approximately 60 nanometers. However, other values and ranges are within the scope of the present disclosure. In some implementations, a ratio of the second depth to the first depth is included in a range of approximately 1.1:1 to approximately 60:1. However, other values and ranges are within the scope of the present disclosure.

The second etch operation may be different from the first etch operation in that the first etch operation is performed using a first etchant, and the second etch operation is performed using a second etchant that is different than the first etchant. For example, the first etch operation may be performed using a plasma-based etchant and the second etch operation may be performed using a gas-based etchant.

Different etchants may be used for the first etch operation and the second etch operation to achieve different etch selectivity for the first etch operation and the second etch operation. For example, the first etchant used in the first etch operation may be selected to achieve a low etch selectivity between the dielectric layers above the source/drain region 505 (e.g., the dielectric layer 605, the ESL 805, the dielectric layer 810) and the semiconductor material of the source/drain region 505 (e.g., the semiconductor material of the second epitaxial layer 515). This enables the contact recess 815 to be formed through the dielectric layer 605, the ESL 805, the dielectric layer 810, and into the source/drain region 505 in the first etch operation.

For the second etch operation, the second etchant may be selected to achieve a high etch selectivity between the dielectric layers above the source/drain region 505 (e.g., the dielectric layer 605, the ESL 805, the dielectric layer 810, the sidewall liners 820) and the semiconductor material of the source/drain region 505 (e.g., the semiconductor material of the first epitaxial layer 510, the semiconductor material of the second epitaxial layer 515). In particular, a gas-based etchant such as a chlorine-containing gas and/or another suitable gas-based etchant may be used in the second etch operation so that the etch rate of the second etchant for the semiconductor material of the source/drain region 505 is greater than the etch rate of the second etchant for the dielectric material of the sidewalls (e.g., the silicon nitride material of the sidewall liners 820) of the contact recess 815. This enables the depth of the contact recess 815 to be increased in the source/drain region 505 with minimal to no etching of the dielectric material of the sidewalls of the contact recess 815 (and thus, minimal to no increase in the lateral width of the contact recess 815).

As shown in FIG. 8E, a metal silicide layer 825 is formed at the bottom of the contact recess 815. In particular, the metal silicide layer 825 may be formed from the surface of the source/drain region 505 (e.g., the surface of the first epitaxial layer 510 of the source/drain region 505, the surface of the second epitaxial layer 515 of the source/drain region 505) exposed in the contact recess 815.

To form the metal silicide layer 825, a salicidation process may be performed. The salicidation process includes using a deposition tool to deposit (e.g., by CVD, ALD, PVD, and/or electroplating) a layer of metal material on the exposed surfaces of the merged region 520 of the first epitaxial layer 510 of the source/drain region 505 exposed in the contact recess 815, and on the exposed surfaces of the second epitaxial layer 515 of the source/drain region 505 exposed in the contact recess 815. An annealing operation may be performed to increase the temperature of the layer of metal material, the exposed surfaces of the first epitaxial layer 510, and the exposed surfaces of the second epitaxial layer 515 of the source/drain region 505 to cause the metal material to diffuse into the exposed surfaces of the merged region of the first epitaxial layer 510, and into the exposed surfaces of the second epitaxial layer 515. This results in formation of the metal silicide layer 825. In other words, the exposed surfaces of the merged region of the first epitaxial layer 510 and the exposed surfaces of the second epitaxial layer 515 of the source/drain region 505 may be transformed from a semiconductor surface to a metal silicide surface.

In some implementations, the layer of metal material includes titanium (Ti) and the metal silicide layer 825 includes titanium silicide (TiSi). In some implementations, the layer of metal material includes ruthenium (Ru) and the metal silicide layer 825 includes ruthenium silicide (RuSi). In some implementations, the layer of metal material includes cobalt (Co) and the metal silicide layer 825 includes cobalt silicide (CoSi).

The metal silicide layer 825 is formed to a thickness (indicated in FIG. 8E as a dimension D3) that is included in a range of approximately 3.5 nanometers to approximately 7 nanometers. However, other values and ranges are within the scope of the present disclosure. A lateral distance between the metal silicide layer 825 and a gate structure 710 laterally adjacent to the source/drain region 505 (indicated in FIG. 8E as a dimension D4) may be included in a range of approximately 2 nanometers to approximately 20 nanometers. However, other values and ranges are within the scope of the present disclosure.

As shown in FIG. 8F, the remaining area in the contact recess 815 may be filled in with material of a metal core 830 and a source/drain contact 835 such that the metal core 830 is laterally surrounded by the epitaxial layer(s), 510, 515 of the source/drain region 505. The source/drain contact 835 may be referred to as a front side source/drain contact in that the source/drain contact 835 is formed above the front side of the semiconductor device 105. The metal core 830 may correspond to a bottom portion of the source/drain contact 835 that is recessed within the source/drain region 505. The sidewall liners 820 may be located between the source/drain contact 835 and the dielectric layer 605, between the source/drain contact 835 and the ESL 805, and/or between the source/drain contact 835 and the dielectric layer 810.

The source/drain contact 835 may include a contact plug, a via, a conductive column, a conductive pillar, and/or another type of conductive structure that is elongated in the z-direction in the semiconductor device 105. The metal core 830 and the source/drain contact 835 may each include one or more electrically conductive materials such as tungsten (W), ruthenium (Ru), cobalt (Co), titanium (Ti), molybdenum (Mo), copper (Cu), and/or aluminum (Al), among other examples. In some implementations, the metal core 830 and the source/drain contact 835 are formed of the same material. In some implementations, the metal core 830 and the source/drain contact 835 are formed of different materials.

A deposition tool may be used to deposit the material of the metal core 830 and the material of the source/drain contact 835 in the contact recess 815 using a CVD technique, an ALD technique, a PVD technique, an electroplating technique, and/or another suitable deposition technique. In some implementations, a seed layer is deposited in the contact recess 815, and the material of the source/drain contact 835 is deposited on the seed layer.

The metal core 830 of the source/drain region 505 effectively enables the source/drain contact 835 and the metal silicide layer 825 to extend into the source/drain region 505 to a depth corresponding to the dimension D2. The bottom of the metal core 830 may be located at a depth (indicated in FIG. 8F as dimension D5) that is located at a depth that is lower in the semiconductor device 105 than the bottom-most nanostructure channels 315 (e.g., the nanostructure channels 315c). This may reduce the contact resistance between the source/drain contact 835 and the source/drain region 505 because of the increased contact area between the source/drain contact 835 and the source/drain region 505. Moreover, this may reduce current crowding in the source/drain region 505 because the metal core 830 extends alongside the top-most nanostructure channels (e.g., the nanostructure channels 315a), alongside the middle nanostructure channels (e.g., the nanostructure channels 315b), and alongside the bottom-most nanostructure channels (e.g., the nanostructure channels 315c). This provides for a more direct lateral path of travel for charge carriers between the source/drain contact 835 and the nanostructure channels 315 through the source/drain region 505 (e.g., as opposed to the charge carriers having to travel vertically in addition to horizontally to reach the nanostructure channels 315a-315c).

As shown in FIG. 8G, a planarization tool may be used to perform a planarization operation (e.g., a CMP operation) to planarize the semiconductor device 105. In the planarization operation, excess material of the source/drain contact 835 is removed, and the dielectric layer 810 may be removed. The planarization operation may be stopped once the ESL 805 is reached.

In some implementations, additional front side processing operations may be performed on the front side of the semiconductor device 105. For example, a front side interconnect layer (e.g., a front side back end region or a front side back end of line (BEOL) region) of the semiconductor device 105 may be formed above a device layer of the semiconductor device 105 containing the nanostructure transistors (e.g., corresponding to the nanostructure channels 315, the gate structures 710, and the source/drain regions 505). The source/drain contacts 835 may electrically connect the source/drain regions 505 of the nanostructure transistors to conductive structures in the front side interconnect layer. This enables electrical signals and/or electrical power to be routed between one or more conductive structures (not shown) in the front side interconnect layer and the source/drain regions 505 through the source/drain contacts 835.

As another example, the front side of the semiconductor device 105 may be bonded to another semiconductor device to form a three-dimensional (3D) stacked semiconductor device. The bonding structures (e.g., bonding pads, bonding vias, a bonding dielectric layer) above the front side interconnect layer may be bonded to bonding structures of the other semiconductor device.

As shown in FIG. 8H, the semiconductor device 105 may be flipped so that back side processing may be performed on the back side of the semiconductor device 105 (e.g., after the front side processing of the semiconductor device 105). “Back side” of the semiconductor device 105 may refer to a side of the semiconductor device 105 vertically opposite the front side. In other words, back side of the semiconductor device 105 may refer to a side of the semiconductor substrate 110 vertically opposite the front side above which the layer stack 115 was formed.

The back side processing may include forming a contact recess (e.g., a back side contact recess) 840 into the back side of the semiconductor device 105. The contact recess 840 may extend through the semiconductor substrate 110, through the fin portion 160, and through the merged region 520 of the first epitaxial layer 510 of the source/drain region 505 so that the bottom of the metal silicide layer 825 is exposed through the contact recess 840. In some implementations, the semiconductor substrate 110 is removed prior to formation of the contact recess 840 (e.g., in a wafer grinding operation). In some implementations, the contact recess 840 extends into a portion of the metal silicide layer 825 such that a bottom surface of the contact recess 840 is recessed in the metal silicide layer 825.

In some implementations, a pattern in a photoresist layer is used to etch the semiconductor substrate 110, the fin portion 160, the merged region 520 of the first epitaxial layer 510 of the source/drain region 505, and/or the metal silicide layer 825 to form the contact recess 840. In these implementations, a deposition tool may be used to form the photoresist layer over the back side of the semiconductor device 105 (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern. An etch tool may be used to etch the semiconductor substrate 110, the fin portion 160, the merged region 520 of the first epitaxial layer 510 of the source/drain region 505, and/or the metal silicide layer 825 based on the pattern to form the contact recess 840. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for forming the contact recess 840 based on a pattern.

As further shown in FIG. 8H, sidewall liners 845 may be formed on portions of the sidewalls of the contact recess 840 corresponding to the fin portion 160. The sidewall liners 845 may include one or more dielectric materials. For example, the sidewall liners 845 may include a silicon nitride (SiₓN_{y} such as Si₃N₄), a silicon oxynitride (SiON), a silicon oxycarbide (SiOC), a silicon oxycarbonitride (SiOCN), and/or another suitable dielectric material.

To form the sidewall liners 845, a conformal layer of dielectric material may be deposited on the sidewalls of the contact recess 840 (e.g., corresponding to exposed surfaces of the fin portion 160) and on the bottom surface of the contact recess 840 (e.g., corresponding to the exposed surfaces of the first epitaxial layer 510 and the metal silicide layer 825). A deposition tool may be used to deposit the conformal layer of dielectric material using a deposition technique such as ALD and/or CVD, among other examples.

An etch tool may be used to trim the portion of the conformal layer of dielectric material located on the bottom surface of the contact recess 840 so that the conformal layer of dielectric material is removed from the surfaces of the first epitaxial layer 510 and from the metal silicide layer 825. In this way, the surfaces of the first epitaxial layer 510 and from the metal silicide layer 825 are exposed again through the contact recess 840, and the remaining portions of the conformal layer of dielectric material located on the sidewalls of the contact recess 840 correspond to the sidewall liners 845.

An anisotropic etch technique may be used to trim the portion of the conformal layer of dielectric material located on the bottom surface of the contact recess 840 so that the portions of the conformal layer of dielectric material located on the sidewalls of the contact recess 840 remain as the sidewall liners 845. For example, a plasma-based etch technique (such as an RIE technique) may be used to perform a primarily vertical (e.g., z-direction) etch to trim the conformal layer of dielectric material. However, other etch techniques are within the scope of the present disclosure.

As shown in FIG. 8I, the contact recess 840 may be filled in with material of a source/drain contact 850. The source/drain contact 850 may be referred to as a back side source/drain contact in that the source/drain contact 850 is formed above the back side of the semiconductor device 105. The source/drain contact 850 may be formed such that the source/drain contact 850 lands on and is in contact with the metal silicide layer 825. In this way, the metal silicide layer 825 is shared between the source/drain contacts 835 and 850, as opposed to separate salicidation processes being performed for each of the source/drain contacts 835 and 850.

The source/drain contact 850 may include a contact plug, a via, a conductive column, a conductive pillar, and/or another type of conductive structure that is elongated in the z-direction in the semiconductor device 105. The source/drain contact 835 may include one or more electrically conductive materials such as tungsten (W), ruthenium (Ru), cobalt (Co), titanium (Ti), molybdenum (Mo), copper (Cu), and/or aluminum (Al), among other examples.

A deposition tool may be used to deposit the material of the source/drain contact 850 in the contact recess 840 using a CVD technique, an ALD technique, a PVD technique, an electroplating technique, and/or another suitable deposition technique. In some implementations, a seed layer is deposited in the contact recess 840, and the material of the source/drain contact 850 is deposited on the seed layer. In some implementations, a planarization tool may be used to perform a planarization operation (e.g., a CMP operation) to planarize the back side of the semiconductor device 105. In the planarization operation, excess material of the source/drain contact 850 may be removed.

As indicated above, FIGS. 8A-8I are provided as an example. Other examples may differ from what is described with regard to FIGS. 8A-8I.

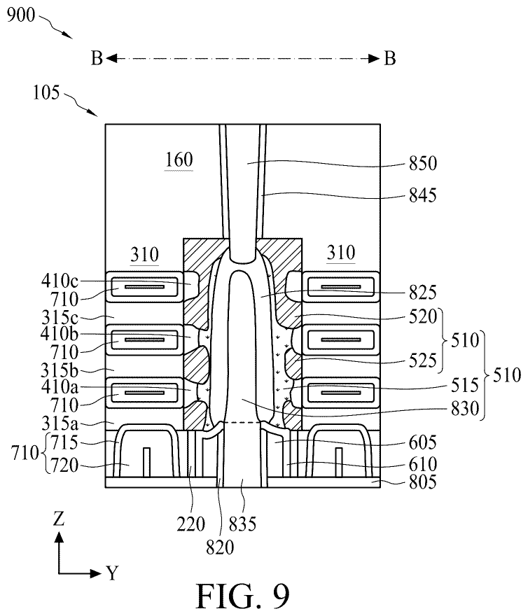

FIG. 9 is a diagram of an example implementation 900 of the semiconductor device 105 described herein. As shown in FIG. 9, the example implementation 900 is similar to the examples illustrated in FIGS. 1-8I. However, in the example implementation 900, the merged region 520 of the first epitaxial layer 510 of the source/drain region 505 has a more pronounced U-shape relative to the merged region 520 of the first epitaxial layer 510 of the source/drain region 505 illustrated in FIGS. 5-8I. As a result, the bottom of the second epitaxial layer 515 of the source/drain region 505 extends lower than the bottom-most nanostructure channels 315 (e.g., the nanostructure channels 315c) and to a depth of the mesa regions 310.

Because of the pronounced U-shape relative to the merged region 520 of the first epitaxial layer 510 of the source/drain region 505, the metal silicide layer 825 is contained within (and formed from) the second epitaxial layer 515 of the source/drain region 505. The metal silicide layer 825 being contained within the second epitaxial layer 515 may enable a lower electrical resistance to be achieved between the metal silicide layer 825 and the source/drain region 505.

As indicated above, FIG. 9 is provided as an example. Other examples may differ from what is described with regard to FIG. 9.

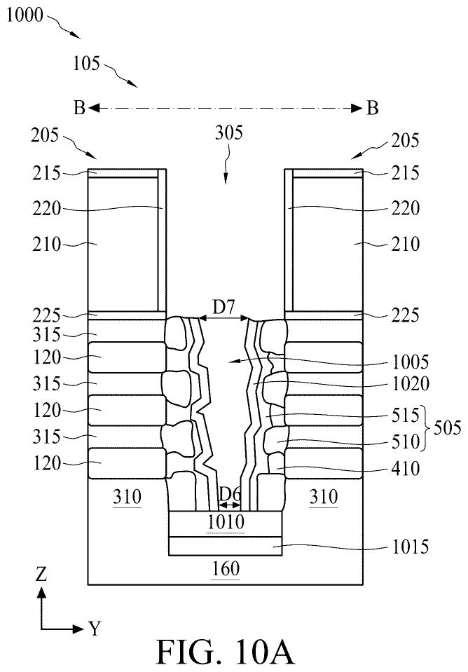

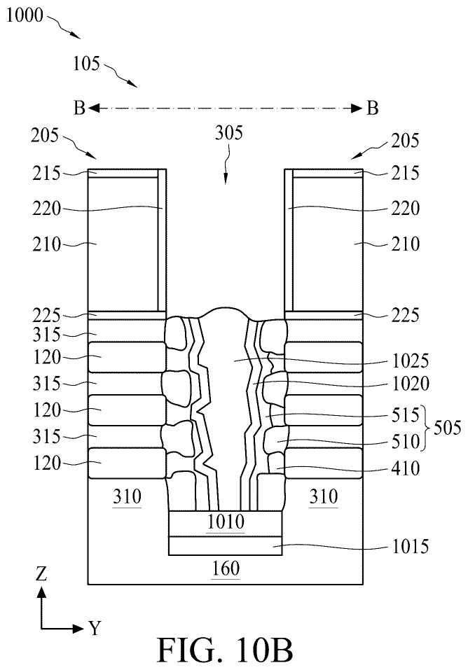

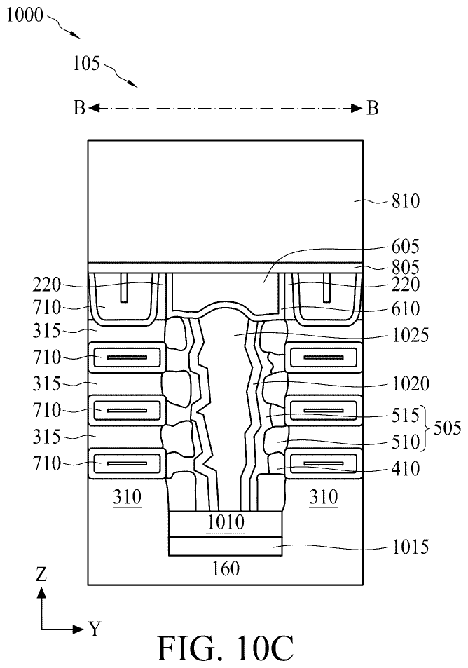

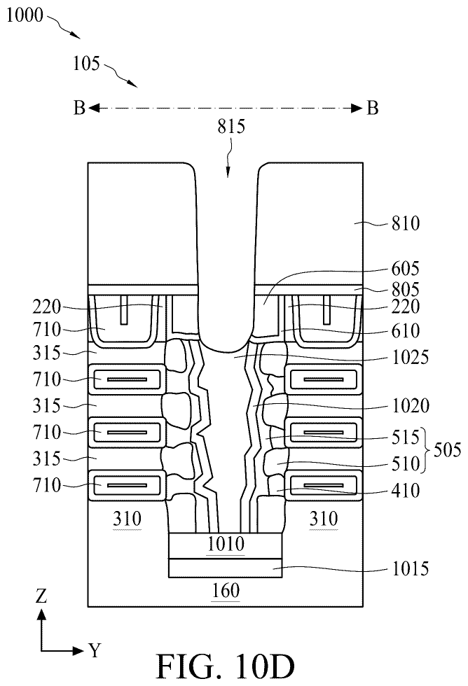

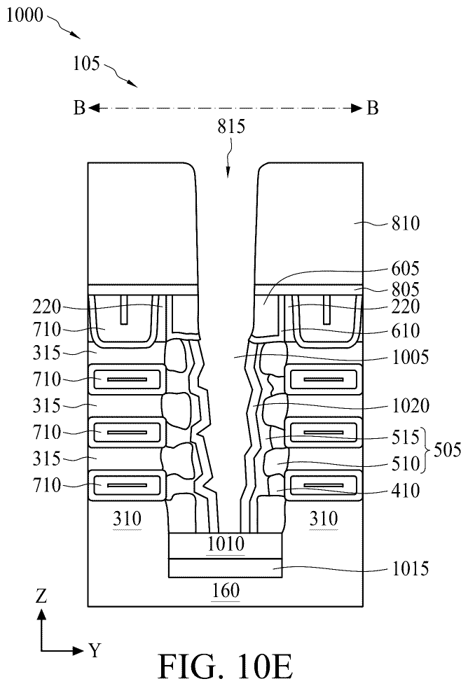

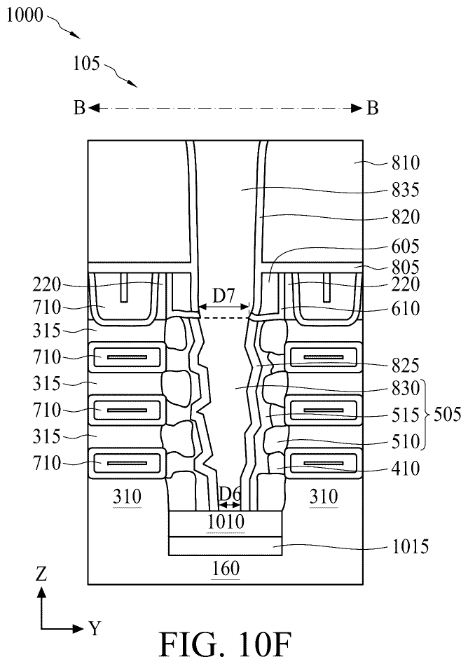

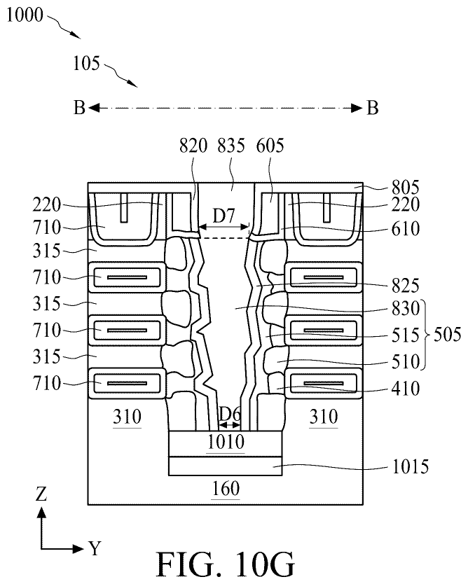

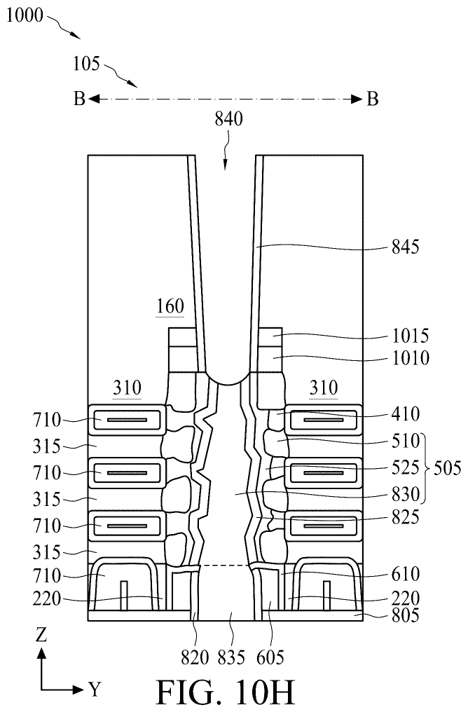

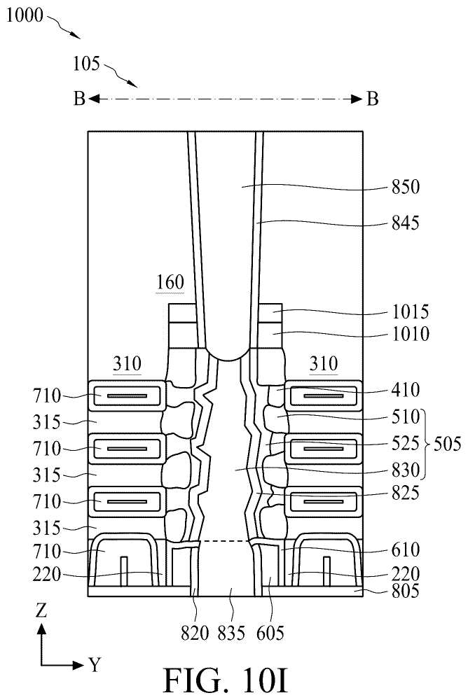

FIGS. 10A-10I are diagrams of an example implementation 1000 of forming the semiconductor device 105 described herein. The example implementation 1000 is similar to the processes described in connection with FIGS. 1A-8I. However, and as shown in FIG. 10A, the one or more epitaxial layers 510, 515 of the source/drain region 505 partially fill the source/drain recess 305, resulting in a hollow core 1005 extending into the source/drain region 505 from the top of the source/drain region 505. The hollow core 1005 is a hollow area within the source/drain region 505 that is not filled in with epitaxial material and is instead filled with air. The hollow core 1005 results from the second epitaxial layer 515 not fully merging and instead being formed along the sidewalls and the bottom surface of the area in the source/drain region 505 not filled in by the first epitaxial layer 510.

The one or more epitaxial layers 510, 515 of the source/drain region 505 are not merged at the bottom of the source/drain recess 305, resulting in the hollow core 1005 extending fully through from the top of the source/drain region 505 to the bottom of the source/drain region 505. As shown in FIG. 10A, in some implementations, a bottom isolation layer 1010 (sometimes referred to as a flexible bottom insulator) may be formed at the bottom of the source/drain recess 305. The bottom isolation layer 1010 may include one or more materials that inhibit epitaxial growth of the one or more epitaxial layers 510, 515 of the source/drain region 505 on the bottom of the source/drain recess 305, which facilitates formation of the hollow core 1005. For example, the bottom isolation layer 1010 may include a silicon nitride (SiₓN_{y} such as Si₃N₄), silicon oxycarbide (SiOC), silicon oxycarbonitride (SiOCN), and/or silicon carbonitride (SiCN), among other examples.

Since the bottom isolation layer 1010 inhibits epitaxial growth of the one or more epitaxial layers 510, 515 of the source/drain region 505 on the bottom of the source/drain recess 305, the epitaxial growth of the one or more epitaxial layers 510, 515 may be primarily on the sidewalls of the source/drain region 505. For example, a deposition tool may be used to perform an epitaxial deposition operation in which material of the first epitaxial layer 510 grows on the exposed ends of the nanostructure channels 315 and on the exposed ends of the mesa regions 310 in the source/drain recess 305. The exposed ends of the nanostructure channels 315 and on the exposed ends of the mesa regions 310 function as a growth substrate for the first epitaxial layer 510. A deposition tool may be used to perform another epitaxial deposition operation in which material of the second epitaxial layer 515 grows on the first epitaxial layer 510 so that the epitaxial material of the second epitaxial layer 515 merges together to form a continuous layer of epitaxial material on the sidewalls of the source/drain recess 305.

A deposition tool may be used to deposit the bottom isolation layer 1010 using a PVD technique, an ALD technique, a CVD technique, an oxidation technique, and/or another suitable deposition technique. In some embodiments, the bottom isolation layer 1010 may be formed to a thickness that is included in a range of approximately 1 nanometer to about 5 nanometers.

However, other values and ranges are within the scope of the present disclosure.

In some implementations, a buffer region 1015 is first formed in the source/drain recess 305, and the bottom isolation layer 1010 is formed on the buffer region 1015. In some implementations, the buffer region 1015 and/or the bottom isolation layer 1010 are omitted from the semiconductor device 105. The buffer region 1015 may include a layer of semiconductor material that is epitaxially grown at the bottom of the source/drain recess 305.

As further shown in FIG. 10A, a capping layer 1020 may be formed on the second epitaxial layer 515. The capping layer 1020 may include an undoped semiconductor material such as undoped silicon (Si). In some implementations, the capping layer 1020 includes amorphous undoped silicon (Si), and is formed so that the capping layer 1020 can be consumed to form a metal silicide layer 825 on the second epitaxial layer 515 (e.g., instead of, or in addition to, consuming material of the second epitaxial layer 515 to form the metal silicide layer 825). A deposition tool may be used to perform an epitaxial deposition operation in which material of the capping layer 1020 grows on the second epitaxial layer 515.

As further shown in FIG. 10A, the hollow core 1005 of the source/drain region 505 may have a tapered cross-sectional profile in which a bottom width (e.g., in the y-direction) of the hollow core 1005 (indicated in FIG. 10A as a dimension D6) is less than a top width (e.g., in the y-direction) of the hollow core 1005 (indicated in FIG. 10A as a dimension D7). The width of the hollow core 1005 may decrease from the top of the hollow core 1005 to the bottom of the hollow core 1005. In some implementations, the tapered cross-sectional profile of the hollow core 1005 results from the source/drain recess 305 having a similar tapered cross-sectional profile. In some implementations, the tapered cross-sectional profile of the hollow core 1005 results from epitaxial growth of the one or more epitaxial layers 510, 515 of the source/drain region 505 being greater at the bottom of the source/drain region 505 than at the top of the source/drain region 505.

As shown in FIG. 10B, the hollow core 1005 in the source/drain region 505 is filled in with sacrificial material to form a sacrificial plug 1025 in the hollow core 1005. The sacrificial plug 1025 may be a temporary structure that is subsequently removed and replaced with a metal core 830 (or a portion of a source/drain contact 850 that extends into the source/drain region 505). The sacrificial plug 1025 enables subsequent processes to be performed prior to formation of the source/drain contact, such as a replacement gate process to replace the dummy gate structures 205 with metal gate structures.

In some implementations, the material of the sacrificial plug 1025 is different from the material of the one or more epitaxial layers 510, 515 of the source/drain region 505, and/or is different from the material of the inner spacers 410. This enables an etchant to be used to selectively remove the sacrificial plug 1025 with minimal to no removal of material from the one or more epitaxial layers 510, 515 of the source/drain region 505 and material from the inner spacers 410.

In some implementations, the material of the sacrificial plug 1025 includes a semiconductor material that is different from the semiconductor material of the one or more epitaxial layers 510, 515. For example, the one or more epitaxial layers 510, 515 may include doped silicon and/or silicon germanium, and the sacrificial plug 1025 may include germanium (Ge). The germanium concentration in the sacrificial plug 1025 may be greater than the germanium concentration in the one or more epitaxial layers 510, 515. In some implementations, the material of the sacrificial plug 1025 includes a metal-oxide material such as aluminum oxide (AlₓO_{y} such as Al₂O₃), hafnium oxide (HfOₓ such as HfO₂), and/or zirconium oxide (ZrOₓ such as ZrO₂), among other examples.

As shown in FIG. 10C, the dielectric layer 605 may be formed in a similar manner as described in connection with FIG. 6, the gate structures 710 may be formed in a similar manner as described in connection with FIGS. 7A and 7B, and the ESL 805 and the dielectric layer 810 may be formed in a similar manner as described in connection with FIG. 8A.

As shown in FIG. 10D, a first etch operation may be performed to form the contact recess 815 (e.g., the front side contact recess) through the dielectric layer 810, through the ESL 805, through the dielectric layer 605, and to the sacrificial plug 1025 after the replacement gate process of FIGS. 7A and 7B is formed. The contact recess 815 may be formed in a similar manner as described in connection with FIG. 8B.

As shown in FIG. 10E, a second etch operation is performed (e.g., after the first etch operation described in connection with FIG. 10C) to remove the sacrificial plug 1025 from the hollow core 1005 of the source/drain region 505. Removing the sacrificial plug 1025 reveals the hollow core 1005. The second etch operation may be different from the first etch operation in that the first etch operation is performed using a first etchant, and the second etch operation is performed using a second etchant that is different than the first etchant. For example, the first etch operation may be performed using a plasma-based etchant and the second etch operation may be performed using a gas-based etchant or a wet etchant.

Different etchants may be used for the first etch operation and the second etch operation to achieve different etch selectivity for the first etch operation and the second etch operation. For example, the first etchant used in the first etch operation may be selected to achieve a low etch selectivity between the dielectric layers above the source/drain region 505 (e.g., the dielectric layer 605, the ESL 805, the dielectric layer 810) and the material of the sacrificial plug 1025. This enables the contact recess 815 to be formed through the dielectric layer 605, the ESL 805, the dielectric layer 810, and into the sacrificial plug 1025 in the first etch operation.

For the second etch operation, the second etchant may be selected to achieve a high etch selectivity between the dielectric layers above the source/drain region 505 (e.g., the dielectric layer 605, the ESL 805, the dielectric layer 810) and the material of the sacrificial plug 1025, as well as between the material of the sacrificial plug 1025 and the one or more epitaxial layers 510, 515 (e.g., the semiconductor material of the one or more epitaxial layers 510, 515) of the source/drain region 505. For example, the one or more epitaxial layers 510, 515 of the source/drain region 505 may include doped silicon, the material of the sacrificial plug 1025 may include germanium, and a wet etchant such as a mixed solution including hydrogen peroxide (H₂O₂), acetic acid (CH₃COOH), and/or hydrogen fluoride (HF), may be used to etch the sacrificial plug 1025. As another example, the one or more epitaxial layers 510, 515 of the source/drain region 505 may include doped silicon, the material of the sacrificial plug 1025 may include a metal-oxide material, and an etchant such as hydrogen fluoride (HF), phosphoric acid (H₃PO₄), and/or hydrochloric acid (HCl) may be used to etch the sacrificial plug 1025.

In some implementations, some intermixing between the sacrificial plug 1025 and the second epitaxial layer 515 of the source/drain region 505 occurs. In these implementations, some material of the second epitaxial layer 515 may be removed during the second etch operation.

As shown in FIG. 10F, the sidewall liners 820 may be formed on the sidewalls of the contact recess 815 above the hollow core 1005 in a similar manner as described in connection with FIG. 8C.

As further shown in FIG. 10F, the metal silicide layer 825 may be formed in the hollow core 1005. The metal silicide layer 825 may be formed in a similar manner as described in connection with FIG. 8E, except that the capping layer 1020 is consumed to form the metal silicide layer 825, with minimal to no material of the first epitaxial layer 510 and second epitaxial layer 515 being consumed to form the metal silicide layer 825. Since the one or more epitaxial layers 510, 515 of the source/drain region 505 are not merged at the bottom of the hollow core 1005, the metal silicide layer 825 may extend from a top of the hollow core 1005 to a bottom of the hollow core 1005 to the underlying bottom isolation layer 1010.

As further shown in FIG. 10F, the metal core 830 of the source/drain region 505 is formed on the metal silicide layer 825 in the hollow core 1005, and the remaining area in the contact recess 815 is filled in with material of the source/drain contact 835. The metal core 830 and the source/drain contact 835 may be formed in a similar manner as described in connection with FIG. 8F. However, since the one or more epitaxial layers 510, 515 of the source/drain region 505 are not merged at the bottom of the hollow core 1005, the metal core 830 extends from a top of the hollow core 1005 to a bottom of the hollow core 1005 to the underlying bottom isolation layer 1010 in the example implementation 1000. In other words, the metal core 830 may fully extend through the source/drain region 505 from the top of the source/drain region 505 to the bottom of the source/drain region 505. Thus, the bottom of the metal core 830 may be located at a vertical (z-direction) position that is lower in the semiconductor device 105 than the bottom-most nanostructure channels 315 (e.g. nanostructure channels 315c), and that is lower in the semiconductor device 105 than the bottom-most inner spacers 410 (e.g. inner spacers 410c). In some implementations, the bottom of the metal core 830 may be located at a vertical (z-direction) position corresponding to the mesa regions 310 (or the bottoms of the mesa regions 310).

In this way, the sacrificial plug 1025 is formed in the hollow core 1005 of the source/drain region 505 prior to the replacement gate process, and the sacrificial plug 1025 is removed from the hollow core 1005 so that the metal core 830 is formed in the hollow core 1005 after the replacement gate process.

As shown in FIG. 10G, a planarization tool may be used to perform a planarization operation (e.g., a CMP operation) to planarize the semiconductor device 105. In the planarization operation, excess material of the source/drain contact 835 is removed, and the dielectric layer 810 may be removed. The planarization operation may be stopped once the ESL 805 is reached.

As further shown in FIG. 10G, the metal core 830 of the source/drain region 505 may have a tapered cross-sectional profile in which a bottom width (e.g., in the y-direction) of the metal core 830 (dimension D6) is less than a top width (e.g., in the y-direction) of the metal core 830 (dimension D7). The width of the metal core 830 may decrease from the top of the source/drain region 505 to the bottom of the source/drain region 505 in that the metal core 830 may conform to the profile of the hollow core 1005.

As shown in FIG. 10H, the semiconductor device 105 may be flipped so that back side processing may be performed on the back side of the semiconductor device 105 (e.g., after the front side processing of the semiconductor device 105). The back side processing may include forming the contact recess 840 (e.g., the back side contact recess) into the back side of the semiconductor device 105. In the example implementation 1000, the contact recess 840 may extend through the semiconductor substrate 110, through the fin portion 160, through the bottom isolation layer 1010, and/or through the buffer region 1015 to the metal core 830 of the source/drain region 505. The contact recess 840 may be formed in a similar manner as described in connection with FIG. 8H.

As further shown in FIG. 10H, the sidewall liners 845 may be formed on portions of the sidewalls of the contact recess 840 corresponding to the fin portion 160, portions of the sidewalls of the contact recess 840 corresponding to the bottom isolation layer 1010, and/or portions of the sidewalls of the contact recess 840 corresponding to the buffer region 1015. The sidewall liners 845 may be formed in a similar manner as described in connection with FIG. 8H.

As shown in FIG. 10I, the contact recess 840 may be filled in with material of the source/drain contact 850 (e.g., the back side source/drain contact) so that the source/drain contact 850 extends through the fin portion 160, through the bottom isolation layer 1010, and/or through the buffer region 1015. The source/drain contact 850 may be formed such that the source/drain contact 850 lands on and is in contact with a portion of metal silicide layer 825, and/or with a portion of the metal core 830. In other words, at least a portion of the bottom surface of the source/drain contact 850 may be in physical contact with the metal core 830. Thus, a first side (e.g., a top side) of the metal core 830 may be in physical contact with the bottom of the source/drain contact 835, and a second side (e.g., a bottom side) of the metal core 830 vertically opposing the first side may be in physical contact with the bottom of the source/drain contact 850. As indicated above, FIGS. 10A-10I are provided as an example. Other examples may differ from what is described with regard to FIGS. 10A-10I.

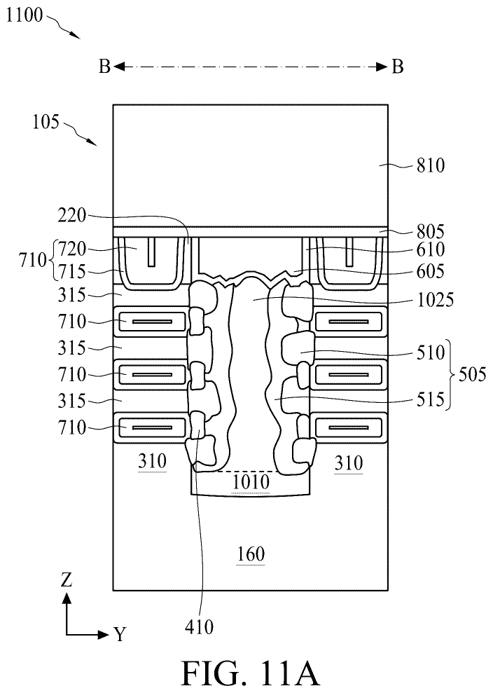

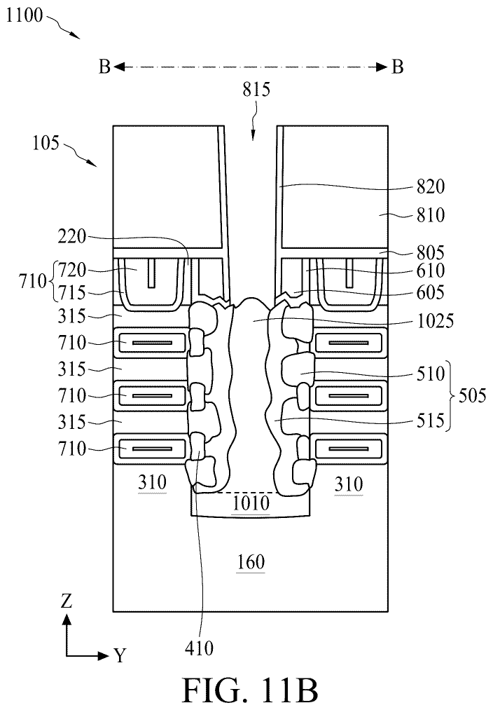

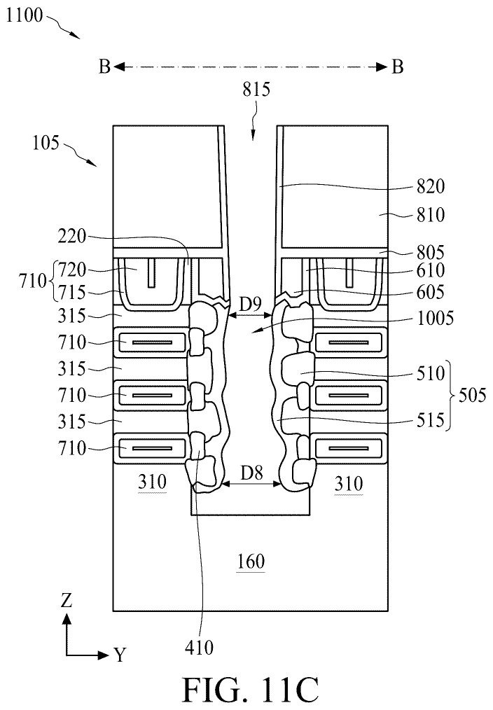

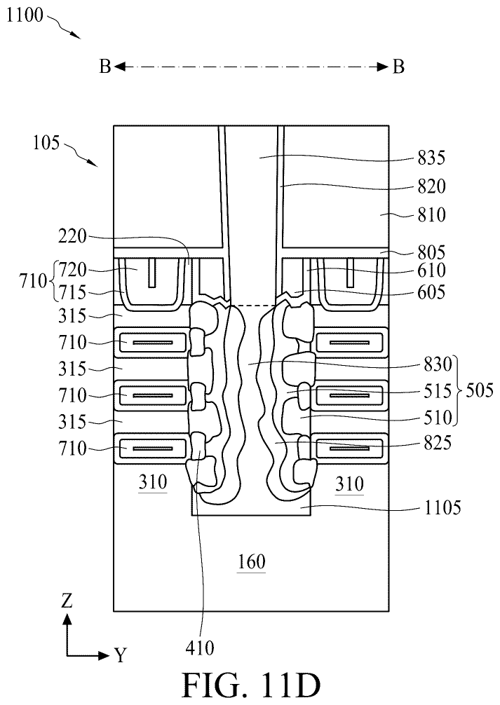

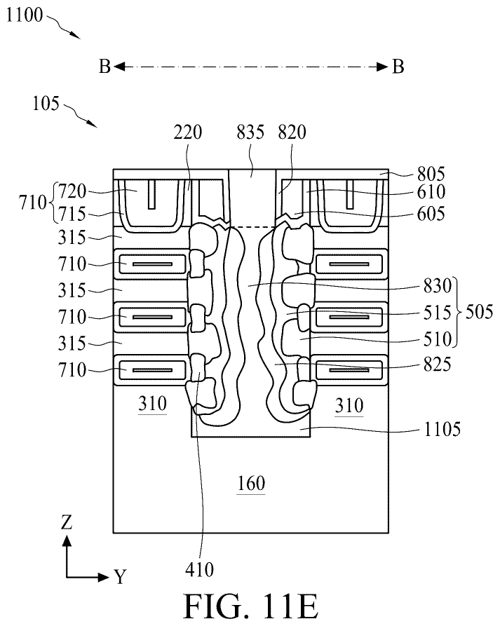

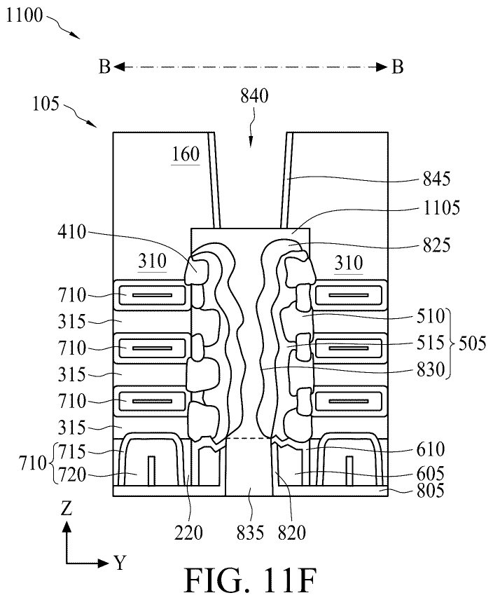

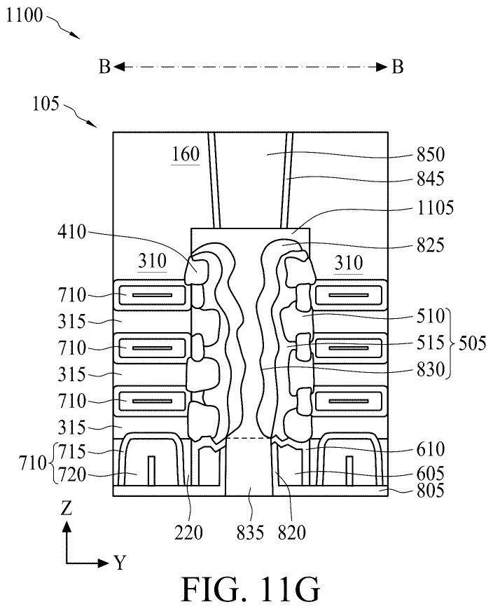

FIGS. 11A-11G are diagrams of an example implementation 1100 of forming the semiconductor device 105 described herein. The example implementation 1100 is similar to the example implementation 1000 described in connection with FIGS. 10A-10I. However, and as shown in FIG. 11A, the bottom isolation layer 1010 may be formed of the same material (or of a material having minimal etch selectivity relative to) as the sacrificial plug 1025 in the example implementation 1100. Moreover, the capping layer 1020 may be omitted in the example implementation 1100.

As shown in FIG. 11B, the dielectric layer 605 may be formed in a similar manner as described in connection with FIG. 6. The gate structures 710 may be formed in a similar manner as described in connection with FIGS. 7A and 7B. The ESL 805 and the dielectric layer 810 may be formed in a similar manner as described in connection with FIG. 8A. The contact recess 815 (e.g., the front side contact recess) and the sidewall liners 820 may be formed in a similar manner as described in connection with FIGS. 8B and 8C.

As shown in FIG. 11C, the sacrificial plug 1025 may be removed through the contact recess 815 in a similar manner as described in connection with FIG. 10E. However, in the example implementation 1100, the bottom isolation layer 1010 may also be removed through the contact recess 815 along with the sacrificial plug 1025. The bottom isolation layer 1010 being formed of the same material as (or of a material having minimal etch selectivity relative to) the sacrificial plug 1025 enables the bottom isolation layer 1010 and the sacrificial plug 1025 to be removed in the same etch operation. In some implementations, an etch tool is used to perform a wet etch operation to remove the bottom isolation layer 1010 and the sacrificial plug 1025 to reveal the hollow core 1005.

As further shown in FIG. 11C, removal of the bottom isolation layer 1010 results in formation of a gap between the fin portion 160 and the one or more epitaxial layers 510, 515 of the source/drain region 505 in the hollow core 1005. Portions of the second epitaxial layer 515 may extend around under bottom-most portions of the first epitaxial layer 510 at the bottom of the hollow core 1005.

As further shown in FIG. 11C, the hollow core 1005 of the source/drain region 505 may have a different cross-sectional profile than the cross-sectional profile illustrated in FIG. 10A in the example implementation 1000. In particular, the hollow core 1005 of the source/drain region 505 in the example implementation 1100 may have a tapered cross-sectional profile in which a bottom width (e.g., in the y-direction) of the hollow core 1005 (indicated in FIG. 11C as a dimension D8) is greater than a top width (e.g., in the y-direction) of the hollow core 1005 (indicated in FIG. 11C as a dimension D9). The width of the hollow core 1005 may be non-uniform from the top of the hollow core 1005 to the bottom of the hollow core 1005.

As shown in FIG. 11D, the metal silicide layer 825 may be formed in the hollow core 1005 by consuming material of the surfaces of the second epitaxial layer 515 of the source/drain region 505. The metal silicide layer 825 may be formed in a similar manner as described in connection with FIG. 8E. However, as indicated above, portions of the second epitaxial layer 515 may extend under bottom-most portions of the first epitaxial layer 510 at the bottom of the hollow core 1005. As a result, in some implementations, the metal silicide layer 825 may extend under bottom-most portions of the first epitaxial layer 510 at the bottom of the hollow core 1005.

As further shown in FIG. 11D, the metal core 830 may be formed in the hollow core 1005 of the source/drain region 505, and the source/drain contact 835 may be formed in the remaining area of the contact recess 815. The metal core 830 and the source/drain contact 835 may be formed in a similar manner as described in connection with FIG. 8F. However, since the bottom isolation layer 1010 was removed (leaving behind the gap between the one or more epitaxial layers 510, 515 and the fin portion 160), a bottom portion 1105 of the metal core 830 extends under the one or more epitaxial layers 510, 515 and fills in the gap between the one or more epitaxial layers 510, 515 and the fin portion 160.

In this way, the sacrificial plug 1025 is formed in the hollow core 1005 of the source/drain region 505 prior to the replacement gate process, and the sacrificial plug 1025 is removed from the hollow core 1005 so that metal core 830 is formed in the hollow core 1005 after the replacement gate process.

As shown in FIG. 11E, a planarization tool may be used to perform a planarization operation (e.g., a CMP operation) to planarize the semiconductor device 105. In the planarization operation, excess material of the source/drain contact 835 is removed, and the dielectric layer 810 may be removed. The planarization operation may be stopped once the ESL 805 is reached.

As shown in FIG. 11F, the semiconductor device 105 may be flipped so that back side processing may be performed on the back side of the semiconductor device 105 (e.g., after the front side processing of the semiconductor device 105). The back side processing may include forming the contact recess 840 (e.g., the back side contact recess) into the back side of the semiconductor device 105. In the example implementation 1000, the contact recess 840 may extend through the semiconductor substrate 110, through the fin portion 160, through the bottom isolation layer 1010, and/or through the buffer region 1015 to the metal core 830 of the source/drain region 505. The contact recess 840 may be formed in a similar manner as described in connection with FIG. 8H.

As further shown in FIG. 11F, the sidewall liners 845 may be formed on portions of the sidewalls of the contact recess 840 corresponding to the fin portion 160, portions of the sidewalls of the contact recess 840 corresponding to the bottom isolation layer 1010, and/or portions of the sidewalls of the contact recess 840 corresponding to the buffer region 1015. The sidewall liners 845 may be formed in a similar manner as described in connection with FIG. 8H.

As shown in FIG. 11G, the contact recess 840 may be filled in with material of the source/drain contact 850 (e.g., the back side source/drain contact) so that the source/drain contact 850 extends through the fin portion 160, through the bottom isolation layer 1010, and/or through the buffer region 1015. The source/drain contact 850 may be formed such that the source/drain contact 850 lands on and is in contact with a portion of metal silicide layer 825, and/or with a portion of the metal core 830. In other words, at least a portion of the bottom surface of the source/drain contact 850 may be in physical contact with the metal core 830. Thus, a first side (e.g., a top side) of the metal core 830 may be in physical contact with the bottom of the source/drain contact 835, and a second side (e.g., a bottom side) of the metal core 830 vertically opposing the first side may be in physical contact with the bottom of the source/drain contact 850. As indicated above, FIGS. 11A-11G are provided as an example. Other examples may differ from what is described with regard to FIGS. 11A-11G.

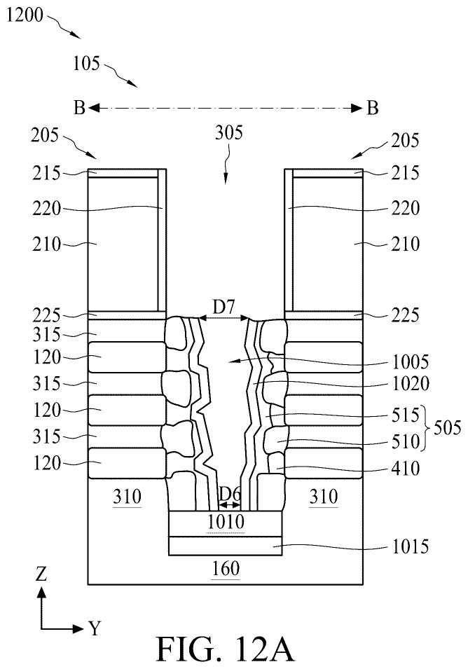

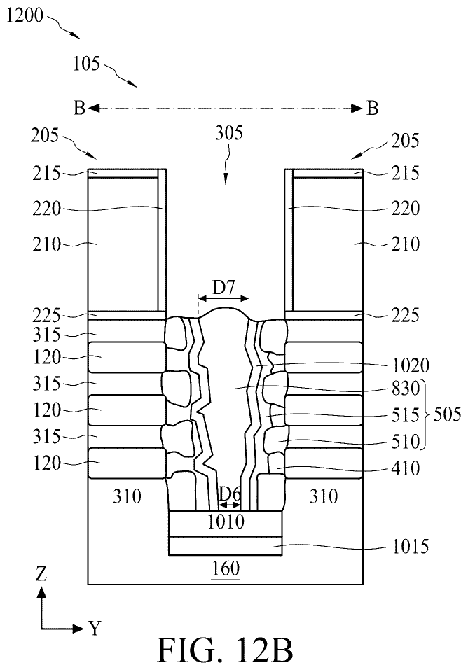

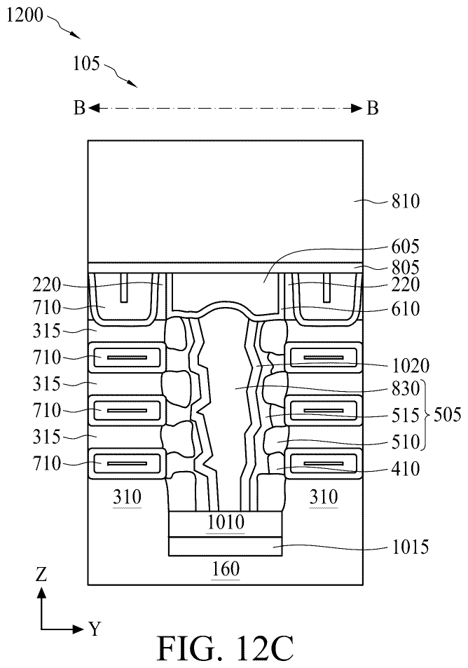

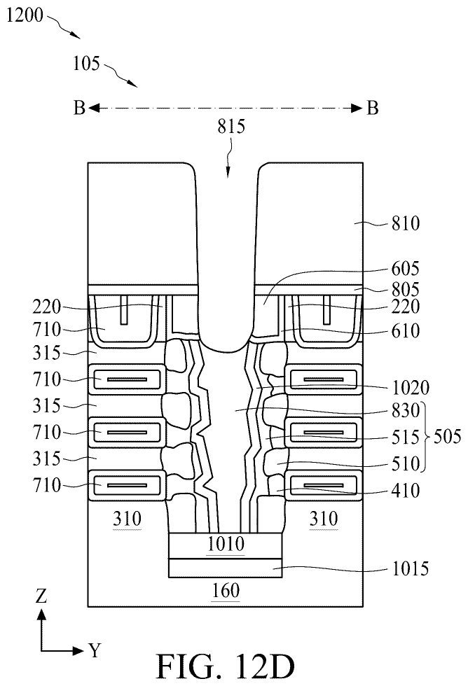

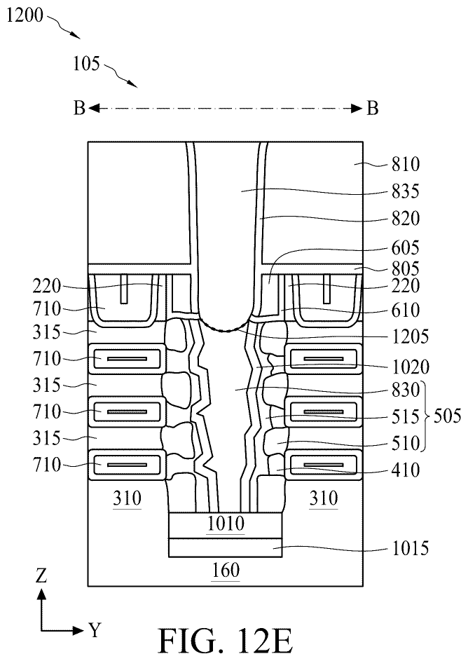

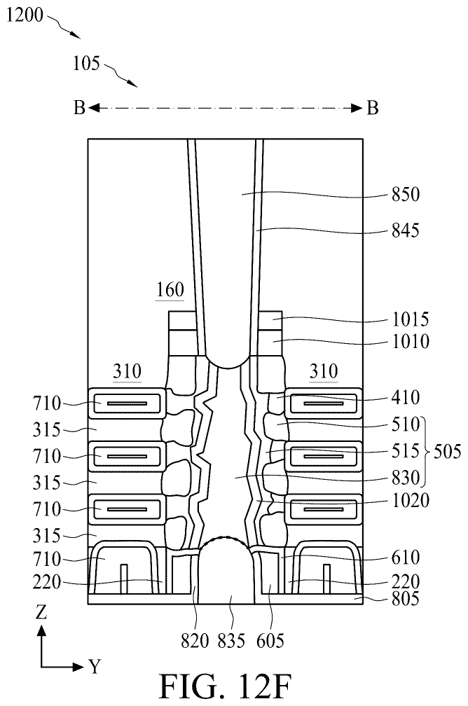

FIGS. 12A-12F are diagrams of an example implementation 1200 of forming the semiconductor device 105 described herein. The example implementation 1200 is similar to the example implementation 1000 described in connection with FIGS. 10A-10I in that the hollow core 1005 extends vertically fully through the source/drain region 505 in the example implementation 1200. Moreover, the metal core 830 is formed in the hollow core 1005 such that the metal core 830 extends vertically fully through the source/drain region 505 in the example implementation 1200.

However, the example implementation 1200 differs from the example implementation 1000 described in connection with FIGS. 10A-10I in that the metal core 830 is formed in the hollow core 1005 through the source/drain recess 305 prior to formation of the dielectric layer 605 and prior to the replacement gate process illustrated in FIGS. 7A and 7B in the example implementation 1200, whereas the metal core 830 is formed in the hollow core 1005 through the contact recess 815 after formation of the dielectric layer 605 and after the replacement gate process illustrated in FIGS. 7A and 7B in the example implementation 1000.

In the example implementation 1200, the sacrificial plug 1025 is omitted, and the metal core 830 is formed in the hollow core 1005 and covered by the dielectric layer 605 (as shown in FIGS. 12A-12C). The metal core 830 may be formed on the capping layer 1020 using a deposition technique such as thermal CVD or plasma-enhanced CVD. The precursor concentration and temperature for the deposition of the material of the metal core 830 may be selected to achieve metal growth for the metal core 830 on the capping layer 1020 (e.g., undoped semiconductor material) at a higher rate than on dielectric layers to achieve selective deposition for the metal core 830.

The metal core 830 may have a tapered cross-sectional profile where the bottom width of the metal core 830 (dimension D6 in FIG. 12B) is less than the top width of the metal core 830 (dimension D7 in FIG. 12B). However, other cross-sectional profiles for the metal core 830 are within the scope of the present disclosure.

As shown in FIGS. 12C-12D, the ESL 805 and the dielectric layer 810 may be formed above the dielectric layer 605, the contact recess 815 may be formed after the replacement gate process illustrated in FIGS. 7A and 7B, and the top of the metal core 830 is revealed through the contact recess 815. In some implementations, the contact recess 815 is formed such that the bottom of the contact recess 815 is recessed within the metal core 830.

As, shown in FIG. 12E, the sidewall liners 820 and the source/drain contact 835 are formed in the contact recess 815 such that the contact recess 815 lands on the top of the metal core 830. In some implementations, the metal core 830 and the source/drain contact 835 are formed of the same electrically conductive material. In some implementations, the metal core 830 and the source/drain contact 835 are formed of different electrically conductive materials.

For example, the metal core 830 may be formed of a high melting point material such as ruthenium (Ru), and the source/drain contact 835 may be formed of a relatively lower melting point material such as cobalt (Co). However, other combinations of materials for the metal core 830 and the source/drain contact 835 are within the scope of the present disclosure.

As indicated above, the contact recess 815 may be formed such that the bottom of the contact recess 815 is recessed within the metal core 830. Thus, the bottom of the source/drain contact 835 may be recessed below the top surface of the metal core 830. Accordingly, an interface 1205 between the metal core 830 and the source/drain contact 835 may have a curved or arc-shaped cross-sectional profile where the curve or arc faces downward in the semiconductor device 105. However, other cross-sectional profiles for the interface 1205 between the metal core 830 and the source/drain contact 835 are within the scope of the present disclosure.

In the example implementation 1200 illustrated in FIGS. 12A-12F, the metal core 830 is illustrated as being formed on the capping layer 1020 of the source/drain region 505 and the metal silicide layer 825 is omitted. However, in other implementations, the capping layer 1020 may be omitted, and the metal silicide layer 825 may be formed on the second epitaxial layer 515 in the source/drain recess 305. In these implementations, the metal core 830 may be formed on the metal silicide layer 825 in the source/drain recess 305.

As shown in FIG. 12F, similar back side processing operations as illustrated and described in connection with FIGS. 10H and 10I may be performed in the example implementation 1200 to form the contact recess 840 (e.g., the back side contact recess), to form the sidewall liners 845 on the sidewalls of the contact recess 840, and/or to form the source/drain contact 850 (e.g., the back side source/drain contact). In some implementations, a portion of the bottom of the source/drain contact 850 is in physical contact with the capping layer 1020.

As indicated above, FIGS. 12A-12F are provided as an example. Other examples may differ from what is described with regard to FIGS. 12A-12F.

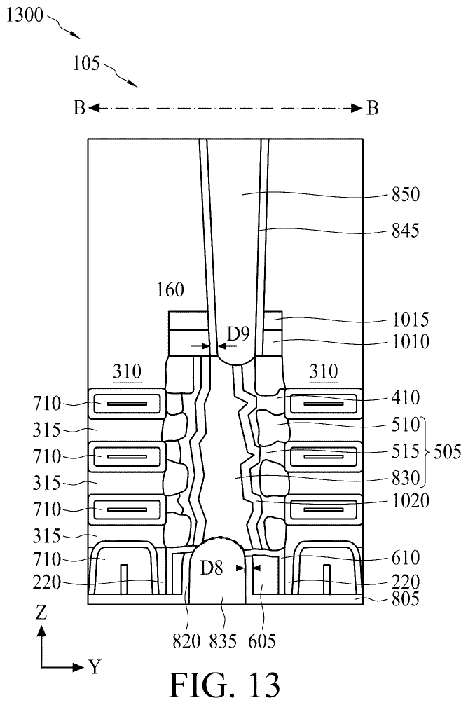

FIG. 13 is a diagram of an example implementation 1300 of the semiconductor device 105 described herein. As shown in FIG. 13, the example implementation 1300 of the semiconductor device 105 is similar to the example implementations illustrated in FIGS. 1-12F in that a source/drain region 505 of a nanostructure transistor of the semiconductor device 105 has a metal core 830 that is electrically coupled to a source/drain contact 835 (e.g., a front side source/drain contact) on a first side of the metal core 830 and a source/drain contact 850 (e.g., a back side source/drain contact) on a second side of the metal core 830 opposing the first side.

However, in the example implementation 1300, the metal core 830 of the source/drain region 505 and the source/drain contact 835 are partially laterally offset by a distance (indicated in FIG. 13 as a dimension D8), and/or the metal core 830 of the source/drain region 505 and the source/drain contact 850 are partially laterally offset by a distance (indicated in FIG. 13 as a dimension D9).

The partial lateral offset between the metal core 830 and the source/drain contact 835 may result from an overlay shift during formation of the contact recess 815. The partial lateral offset may result in a portion of the bottom surface of the source/drain contact 835 being in contact with the capping layer 1020 and/or with the second epitaxial layer 515. Additionally and/or alternatively, the partial lateral offset may result in a portion of the top surface of the metal core 830 being in contact with the sidewall liners 820 and/or with the dielectric layer 605.

The partial lateral offset between the metal core 830 and the source/drain contact 850 may result from an overlay shift during formation of the contact recess 840. The partial lateral offset may result in a portion of the bottom surface of the source/drain contact 850 being in contact with the capping layer 1020 and/or with the second epitaxial layer 515. Additionally and/or alternatively, the partial lateral offset may result in a portion of the bottom surface of the metal core 830 being in contact with the bottom isolation layer 1010.

As indicated above, FIG. 13 is provided as an example. Other examples may differ from what is described with regard to FIG. 13.

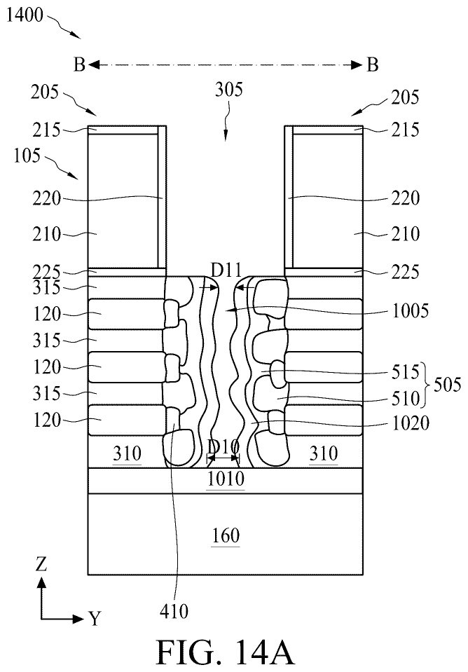

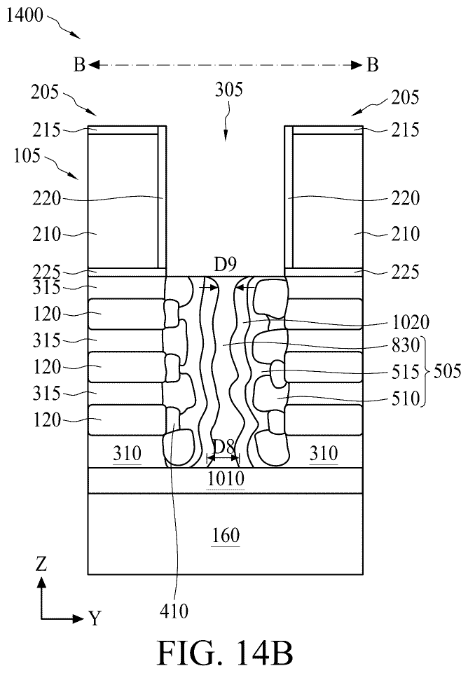

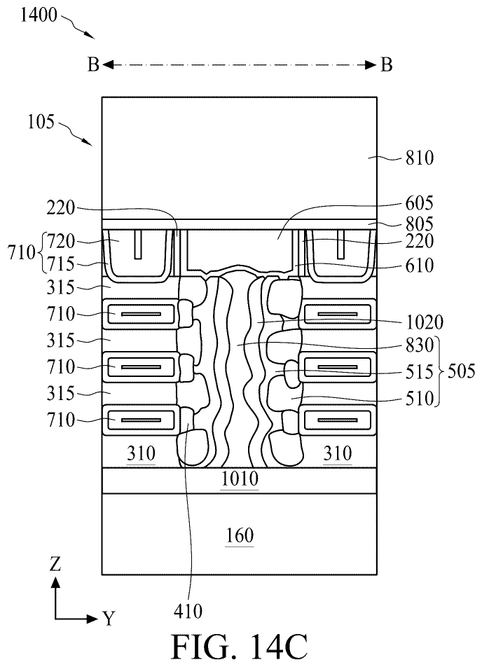

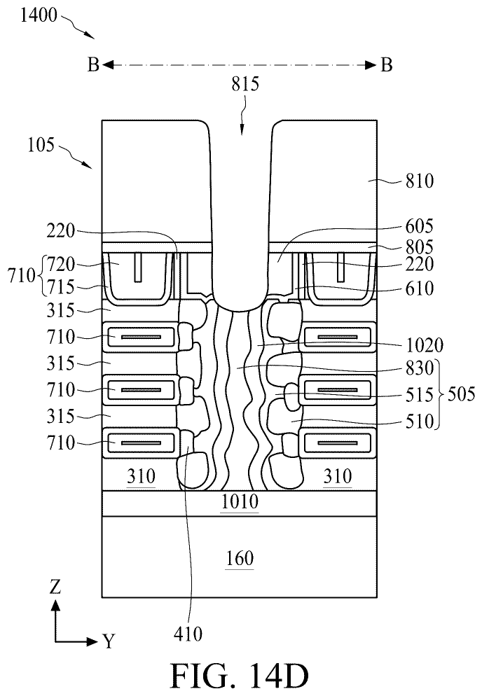

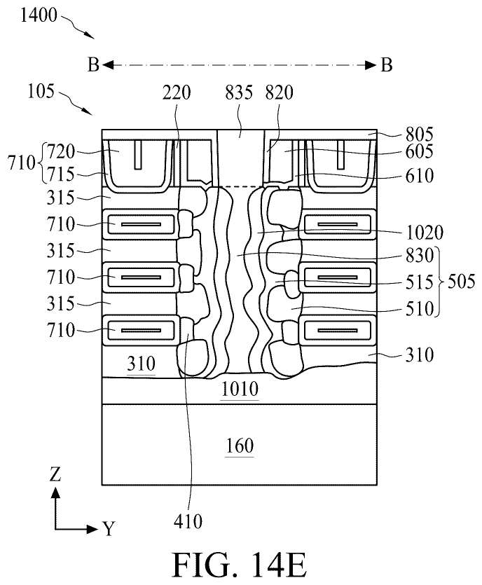

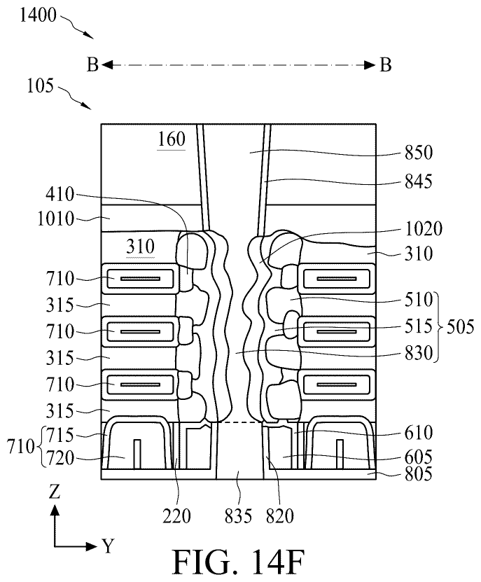

FIGS. 14A-14F are diagrams of an example implementation 1400 of forming the semiconductor device 105 described herein. The example implementation 1400 is similar to the example implementation 1100 described in connection with FIGS. 11A-11G in that the hollow core 1005 extends vertically fully through the source/drain region 505 in the example implementation 1400. Moreover, the metal core 830 is formed in the hollow core 1005 such that the metal core 830 extends vertically fully through the source/drain region 505 in the example implementation 1400.

However, the example implementation 1400 differs from the example implementation 1100 described in connection with FIGS. 11A-11G in that the bottom isolation layer 1010 may extend under the mesa regions 310 in the example implementation 1400, as shown in FIG. 14A. In some implementations, the bottom isolation layer 1010 is formed above the semiconductor substrate 110 prior to formation of the layer stack 115.

The hollow core 1005 may have a tapered cross-sectional profile where the bottom width of the hollow core 1005 (dimension D10 in FIG. 14A) is greater than the top width of the hollow core 1005 (dimension D11 in FIG. 14A). However, other cross-sectional profiles for the hollow core 1005 are within the scope of the present disclosure.

As shown in FIG. 14B, the sacrificial plug 1025 is omitted, and the metal core 830 is formed in the hollow core 1005 through the source/drain recess 305 prior to formation of the dielectric layer 605 and prior to the replacement gate process illustrated in FIGS. 7A and 7B in the example implementation 1400, whereas the metal core 830 is formed in the hollow core 1005 through the contact recess 815 after formation of the dielectric layer 605 and after the replacement gate process illustrated in FIGS. 7A and 7B in the example implementation 1100.

The metal core 830 may land on the bottom isolation layer 1010 exposed in the hollow core 1005.

The metal core 830 may be formed in the hollow core 1005 such that the metal core 830 is in contact with the capping layer 1020. Alternatively, the metal silicide layer 825 may be formed in the hollow core 1005, and the metal core 830 may be formed in the hollow core 1005 such that the metal core 830 is in contact with the metal silicide layer 825.

As shown in FIG. 14C, the metal core 830 is covered by the dielectric layer 605, the ESL 805, and the dielectric layer 810. As shown in FIG. 14D, the contact recess 815 (e.g., the front side contact recess) is formed after the replacement gate process illustrated in FIGS. 7A and 7B, and the top of the metal core 830 is revealed through the contact recess 815. In some implementations, the contact recess 815 is formed such that the bottom of the contact recess 815 is recessed within the metal core 830.

As, shown in FIG. 14E, the sidewall liners 820 and the source/drain contact 835 (e.g., the front side source/drain contact) are formed in the contact recess 815 such that the source/drain contact 835 lands on the top of the metal core 830. The sidewall liners 820, the source/drain contact 835, and/or the dielectric layer 810 may be subsequently planarized.

In some implementations, the metal core 830 and the source/drain contact 835 are formed of the same electrically conductive material. In some implementations, the metal core 830 and the source/drain contact 835 are formed of different electrically conductive materials.

For example, the metal core 830 may be formed of a high melting point material such as ruthenium (Ru), and the source/drain contact 835 may be formed of a relatively lower melting point material such as cobalt (Co). However, other combinations of materials for the metal core 830 and the source/drain contact 835 are within the scope of the present disclosure.

As shown in FIG. 14F, similar back side processing operations as illustrated and described in connection with FIGS. 11F and 10G may be performed in the example implementation 1400 to form the contact recess 840 (e.g., the back side contact recess), to form the sidewall liners 845 on the sidewalls of the contact recess 840, and/or to form the source/drain contact 850 (e.g., the back side source/drain contact). However, in the example implementation 1400, the contact recess 840 is formed through the bottom isolation layer 1010, and the source/drain contact 850 extends through the bottom isolation layer 1010 to the metal core 830 of the source/drain region 505. In some implementations, a portion of the bottom of the source/drain contact 850 is in physical contact with the capping layer 1020.

As indicated above, FIGS. 14A-14F are provided as an example. Other examples may differ from what is described with regard to FIGS. 14A-14F.

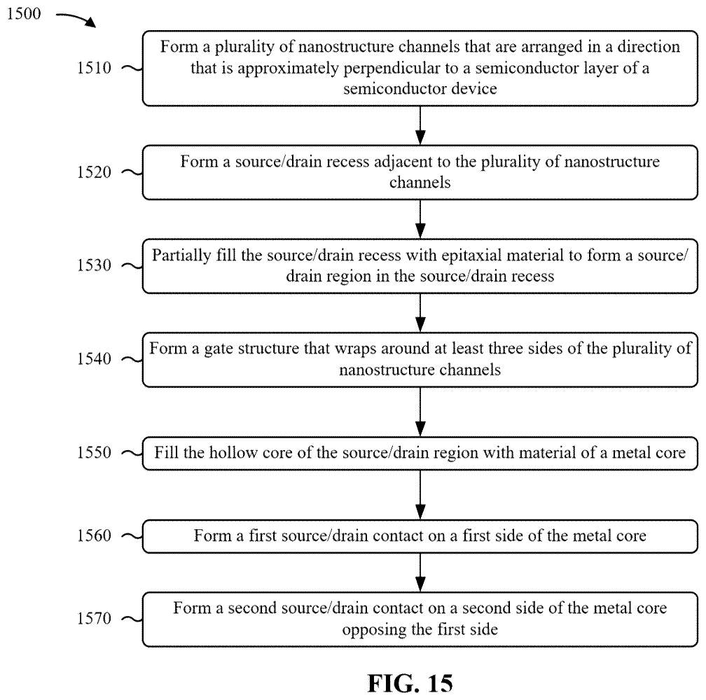

FIG. 15 is a flowchart of an example process 1500 associated with forming a semiconductor device described herein. In some implementations, one or more process blocks of FIG. 15 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 15, process 1500 may include forming a plurality of nanostructure channels that are arranged in a direction that is approximately perpendicular to a semiconductor layer of a semiconductor device (block 1510). For example, one or more semiconductor processing tools may be used to form a plurality of nanostructure channels (e.g., nanostructure channels 315, 315a-315c) that are arranged in a direction (e.g., a z-direction) that is approximately perpendicular to a semiconductor layer (e.g., a semiconductor substrate 110) of a semiconductor device (e.g., a semiconductor device 105), as described herein.

As further shown in FIG. 15, process 1500 may include forming a source/drain recess adjacent to the plurality of nanostructure channels (block 1520). For example, one or more semiconductor processing tools may be used to form a source/drain recess (e.g., a source/drain recess 305) adjacent to the plurality of nanostructure channels, as described herein.

As further shown in FIG. 15, process 1500 may include partially filling the source/drain recess with epitaxial material to form a source/drain region in the source/drain recess (block 1530). For example, one or more semiconductor processing tools may be used to partially fill the source/drain recess with epitaxial material (e.g., a first epitaxial layer 510, a second epitaxial layer 515, a merged region 520, plurality of non-contiguous second epitaxial regions 525) to form a source/drain region (e.g., a source/drain region 505) in the source/drain recess, as described herein. In some implementations, the source/drain region includes a hollow core.

As further shown in FIG. 15, process 1500 may include forming a gate structure that wraps around at least three sides of the plurality of nanostructure channels (block 1540). For example, one or more semiconductor processing tools may be used to form a gate structure (e.g., a gate structure 710) that wraps around at least three sides of the plurality of nanostructure channels, as described herein.

As further shown in FIG. 15, process 1500 may include filling the hollow core of the source/drain region with material of a metal core (block 1550). For example, one or more semiconductor processing tools may be used to fill the hollow core of the source/drain region with material of a metal core (e.g., a metal core 830), as described herein.

As further shown in FIG. 15, process 1500 may include forming a first source/drain contact on a first side of the metal core (block 1560). For example, one or more semiconductor processing tools may be used to form a first source/drain contact (e.g., a source/drain contact 835) on a first side of the metal core, as described herein. In some implementations, the metal core 830 corresponds to a bottom portion of the source/drain contact 835 that is recessed in the source/drain region 505 and laterally surrounded by the one or more epitaxial layers of the source/drain region 505.

As further shown in FIG. 15, process 1500 may include forming a second source/drain contact on a second side of the metal core opposing the first side (block 1570). For example, one or more semiconductor processing tools may be used to form a second source/drain contact (e.g., a source/drain contact 850) on a second side of the metal core opposing the first side, as described herein.

Process 1500 may include additional implementations, such as any single implementation or any combination of implementations described below and/or in connection with one or more other processes described elsewhere herein.

In a first implementation, filling the hollow core of the source/drain region with the material of the metal core includes forming, after forming the gate structure, the first source/drain contact such that the first source/drain contact extends into the hollow core of the source/drain region.

In a second implementation, alone or in combination with the first implementation, process 1500 includes forming a dielectric layer (e.g., a dielectric layer 605) above the source/drain region, and forming, after forming the gate structure, a contact recess (e.g., a contact recess 815) through the dielectric layer and to the hollow core of the source/drain region, where forming the first source/drain contact includes forming the first source/drain contact in the contact recess such that the first source/drain contact extends into the hollow core of the source/drain region.

In a third implementation, alone or in combination with one or more of the first and second implementations, process 1500 includes filling the hollow core with material of a sacrificial plug (e.g., a sacrificial plug 1025) prior to forming the gate structure, and removing, through the contact recess, the sacrificial plug from the hollow core of the source/drain region.

In a fourth implementation, alone or in combination with one or more of the first through third implementations, a material of the sacrificial plug is different than the epitaxial material of the source/drain region.

In a fifth implementation, alone or in combination with one or more of the first through fourth implementations, the material of the sacrificial plug includes at least one of a metal-oxide material or a semiconductor material.

In a sixth implementation, alone or in combination with one or more of the first through fifth implementations, the first source/drain contact is in physical contact with the first side of the metal core, and the second source/drain contact is in physical contact with the second side of the metal core.

In a seventh implementation, alone or in combination with one or more of the first through sixth implementations, filling the hollow core of the source/drain region with the material of the metal core comprises forming the metal core in the hollow core prior to forming the gate structure.

In an eighth implementation, alone or in combination with one or more of the first through seventh implementations, process 1500 includes forming a dielectric layer (e.g., a dielectric layer 605) above the source/drain region after forming the metal core, and forming, after forming the gate structure, a contact recess (e.g., a contact recess 815) through the dielectric layer and to the metal core of the source/drain region, where forming the first source/drain contact includes forming the first source/drain contact in the contact recess such that the first source/drain contact lands on the metal core.

In a ninth implementation, alone or in combination with one or more of the first through eighth implementations, process 1500 includes forming a bottom isolation layer (e.g., a bottom isolation layer 1010) in the source/drain recess, where filling the hollow core of the source/drain region with the material of the metal core includes filling the hollow core of the source/drain region with the material of the metal core such that the material of the metal core lands on the bottom isolation layer.

Although FIG. 15 shows example blocks of process 1500, in some implementations, process 1500 includes additional blocks, fewer blocks, different blocks, or differently arranged blocks than those depicted in FIG. 15. Additionally, or alternatively, two or more of the blocks of process 1500 may be performed in parallel.

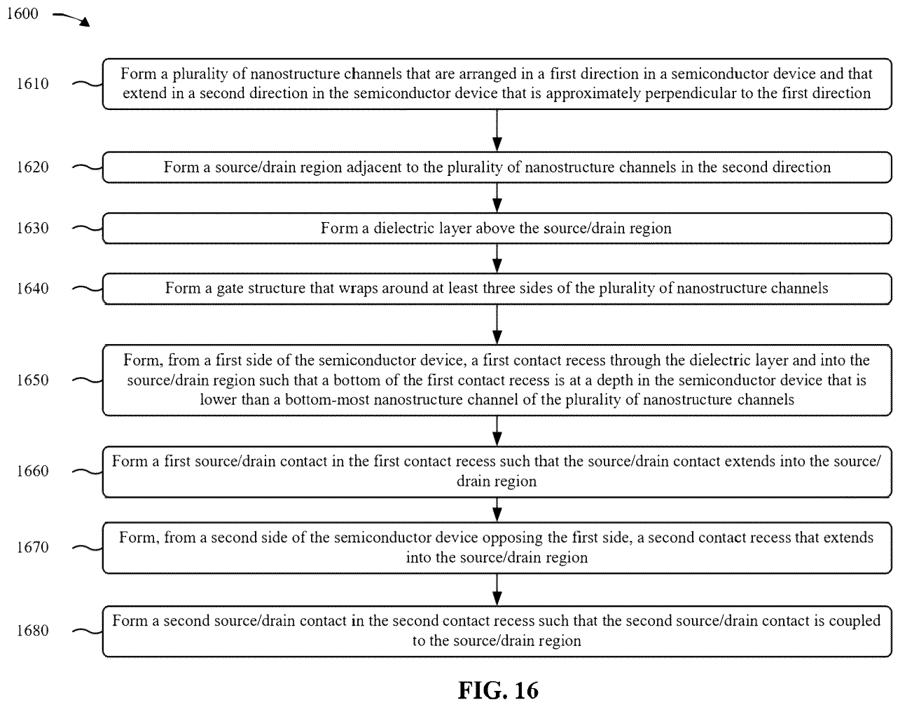

FIG. 16 is a flowchart of an example process 1600 associated with forming a semiconductor device described herein. In some implementations, one or more process blocks of FIG. 16 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 16, process 1600 may include forming a plurality of nanostructure channels that are arranged in a first direction in a semiconductor device and that extend in a second direction in the semiconductor device that is approximately perpendicular to the first direction (block 1610). For example, one or more semiconductor processing tools may be used to form a plurality of nanostructure channels (e.g., nanostructure channels 315, 315a-315c) that are arranged in a first direction (e.g., a z-direction) in a semiconductor device (e.g., a semiconductor device 105) and that extend in a second direction (e.g., a y-direction) in the semiconductor device that is approximately perpendicular to the first direction, as described herein.

As further shown in FIG. 16, process 1600 may include forming a source/drain region adjacent to the plurality of nanostructure channels in the second direction (block 1620). For example, one or more semiconductor processing tools may be used to form a source/drain region (e.g., a source/drain region 505) adjacent to the plurality of nanostructure channels in the second direction, as described herein.

As further shown in FIG. 16, process 1600 may include forming a dielectric layer above the source/drain region (block 1630). For example, one or more semiconductor processing tools may be used to form a dielectric layer (e.g., a dielectric layer 605) above the source/drain region, as described herein.

As further shown in FIG. 16, process 1600 may include forming a gate structure that wraps around at least three sides of the plurality of nanostructure channels (block 1640). For example, one or more semiconductor processing tools may be used to form a gate structure (e.g., a gate structure 710) that wraps around at least three sides of the plurality of nanostructure channels, as described herein.

As further shown in FIG. 16, process 1600 may include forming, from a first side of the semiconductor device, a first contact recess through the dielectric layer and into the source/drain region such that a bottom of the first contact recess is at a depth in the semiconductor device that is lower than a bottom-most nanostructure channel of the plurality of nanostructure channels (block 1650). For example, one or more semiconductor processing tools may be used to form, from a first side of the semiconductor device, a first contact recess (e.g., a contact recess 815) through the dielectric layer and into the source/drain region such that a bottom of the first contact recess is at a depth (e.g., a dimension D2) in the semiconductor device that is lower than a bottom-most nanostructure channel (e.g., a nanostructure channel 315c) of the plurality of nanostructure channels, as described herein.

As further shown in FIG. 16, process 1600 may include forming a first source/drain contact in the first contact recess such that the source/drain contact extends into the source/drain region (block 1660). For example, one or more semiconductor processing tools may be used to form a first source/drain contact (e.g., a source/drain contact 835) in the first contact recess such that the source/drain contact extends into the source/drain region, as described herein.

As further shown in FIG. 16, process 1600 may include forming, from a second side of the semiconductor device opposing the first side, a second contact recess that extends into the source/drain region (block 1670). For example, one or more semiconductor processing tools may be used to form, from a second side of the semiconductor device opposing the first side, a second contact recess (e.g., a contact recess 840) that extends into the source/drain region, as described herein.

As further shown in FIG. 16, process 1600 may include forming a second source/drain contact in the second contact recess such that the second source/drain contact is coupled to the source/drain region (block 1680). For example, one or more semiconductor processing tools may be used to form a second source/drain contact (e.g., a source/drain contact 850) in the second contact recess such that the second source/drain contact is coupled to the source/drain region, as described herein.

Process 1600 may include additional implementations, such as any single implementation or any combination of implementations described below and/or in connection with one or more other processes described elsewhere herein.

In a first implementation, forming the first contact recess includes performing a first etch operation to form the first contact recess such that the bottom of the first contact recess is at a first depth (e.g., a dimension D1) in the source/drain region, and performing a second etch operation to extend the first contact recess from the first depth to the depth that is lower than the bottom-most nanostructure channel.

In a second implementation, alone or in combination with the first implementation, process 1600 includes forming, after the first etch operation and prior to the second etch operation, a protective liner (e.g., a sidewall liner 820) on sidewalls of the first contact recess and on a top of the source/drain region in the first contact recess, and performing, after the first etch operation and prior to the second etch operation, a third etch operation to etch through the protective liner to expose the top of the source/drain region through the first contact recess.

In a third implementation, alone or in combination with one or more of the first and second implementations, performing the second etch operation includes performing the second etch operation while the protective liner is on the sidewalls of the first contact recess.

In a fourth implementation, alone or in combination with one or more of the first through third implementations, forming the first source/drain contact includes forming a metal silicide layer (e.g., a metal silicide layer 825) in the first contact recess, and forming the first source/drain contact on the metal silicide layer.

In a fifth implementation, alone or in combination with one or more of the first through fourth implementations, forming the second source/drain contact in the second contact recess includes forming the second source/drain contact in the second contact recess such that the second source/drain contact is in contact with the metal silicide layer.

Although FIG. 16 shows example blocks of process 1600, in some implementations, process 1600 includes additional blocks, fewer blocks, different blocks, or differently arranged blocks than those depicted in FIG. 16. Additionally, or alternatively, two or more of the blocks of process 1600 may be performed in parallel.

In this way, a source/drain region is formed for a nanostructure transistor of a semiconductor device such that the source/drain region includes a metal core. The metal core provides a greater amount of surface area for a front side source/drain contact and a back side source/drain contact to be coupled to the source/drain region than if the source/drain region were fully filled in with epitaxially-grown semiconductor material. The increased contact surface area provides for reduced contact resistance between the source/drain region and the front side and back side source/drain contacts because of the less-restricted current flow path between the source/drain region and the front side and back side source/drain contacts. In this way, the reduced contact resistance between the source/drain region and the front side and back side source/drain contacts enables a greater power efficiency to be achieved for the nanostructure transistor and/or enables increased switching speeds to be achieved for the nanostructure transistor, among other examples.

As described in greater detail above, some implementations described herein provide a method. The method includes forming a plurality of nanostructure channels that are arranged in a direction that is approximately perpendicular to a semiconductor layer of a semiconductor device. The method includes forming a source/drain recess adjacent to the plurality of nanostructure channels. The method includes partially filling the source/drain recess with epitaxial material to form a source/drain region in the source/drain recess, where the source/drain region includes a hollow core. The method includes forming a gate structure that wraps around at least three sides of the plurality of nanostructure channels. The method includes filling the hollow core of the source/drain region with material of a metal core. The method includes forming a first source/drain contact on a first side of the metal core. The method includes forming a second source/drain contact on a second side of the metal core opposing the first side.

As described in greater detail above, some implementations described herein provide a method. The method includes forming a plurality of nanostructure channels that are arranged in a first direction in a semiconductor device and that extend in a second direction in the semiconductor device that is approximately perpendicular to the first direction. The method includes forming a source/drain region adjacent to the plurality of nanostructure channels in the second direction. The method includes forming a dielectric layer above the source/drain region. The method includes forming a gate structure that wraps around at least three sides of the plurality of nanostructure channels. The method includes forming, from a first side of the semiconductor device, a first contact recess through the dielectric layer and into the source/drain region such that a bottom of the first contact recess is at a depth in the semiconductor device that is lower than a bottom-most nanostructure channel of the plurality of nanostructure channels. The method includes forming a first source/drain contact in the first contact recess such that the source/drain contact extends into the source/drain region. The method includes forming, from a second side of the semiconductor device opposing the first side, a second contact recess that extends into the source/drain region. The method includes forming a second source/drain contact in the second contact recess such that the second source/drain contact is coupled to the source/drain region.

As described in greater detail above, some implementations described herein provide a semiconductor device. The semiconductor device includes a plurality of nanostructure channels arranged in a first direction and that extend in a second direction is approximately perpendicular to the first direction. The semiconductor device includes a gate structure wrapping around the plurality of nanostructure channels. The semiconductor device includes a source/drain region, adjacent to a side of the gate structure and adjacent to ends of the plurality of nanostructure channels, comprising, a metal core one or more epitaxial layers laterally surrounding the metal core. The semiconductor device includes a front side source/drain contact on a front side of the semiconductor device and in electrical connection with a first side of the metal core of the source/drain region. The semiconductor device includes a back side source/drain contact on a back side of the semiconductor device and in electrical connection with a second side of the metal core of the source/drain region opposing the first side.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a plurality of nanostructure channels that are arranged in a direction that is approximately perpendicular to a semiconductor layer of a semiconductor device;
forming a source/drain recess adjacent to the plurality of nanostructure channels;
partially filling the source/drain recess with epitaxial material to form a source/drain region in the source/drain recess,
wherein the source/drain region includes a hollow core;
forming a gate structure that wraps around at least three sides of the plurality of nanostructure channels;
filling the hollow core of the source/drain region with material of a metal core;
forming a first source/drain contact on a first side of the metal core; and
forming a second source/drain contact on a second side of the metal core opposing the first side.

2. The method of claim 1, wherein filling the hollow core of the source/drain region with the material of the metal core comprises:
forming, after forming the gate structure, the first source/drain contact such that the first source/drain contact extends into the hollow core of the source/drain region.

3. The method of claim 2, further comprising:
forming a dielectric layer above the source/drain region; and
forming, after forming the gate structure, a contact recess through the dielectric layer and to the hollow core of the source/drain region,
wherein forming the first source/drain contact comprises:
forming the first source/drain contact in the contact recess such that the first source/drain contact extends into the hollow core of the source/drain region.

4. The method of claim 3, further comprising:
filling the hollow core with material of a sacrificial plug prior to forming the gate structure; and
removing, through the contact recess, the sacrificial plug from the hollow core of the source/drain region.

5. The method of claim 4, wherein a material of the sacrificial plug is different than the epitaxial material of the source/drain region.

6. The method of claim 4, wherein the material of the sacrificial plug comprises at least one of:
a metal-oxide material, or
a semiconductor material.

7. The method of claim 2, wherein the first source/drain contact is in physical contact with the first side of the metal core; and
wherein the second source/drain contact is in physical contact with the second side of the metal core.

8. The method of claim 1, wherein filling the hollow core of the source/drain region with the material of the metal core comprises:
forming the metal core in the hollow core prior to forming the gate structure.

9. The method of claim 8, further comprising:
forming a dielectric layer above the source/drain region after forming the metal core; and
forming, after forming the gate structure, a contact recess through the dielectric layer and to the metal core of the source/drain region,
wherein forming the first source/drain contact comprises:
forming the first source/drain contact in the contact recess such that the first source/drain contact lands on the metal core.

10. The method of claim 1, further comprising:
forming a bottom isolation layer in the source/drain recess, wherein filling the hollow core of the source/drain region with the material of the metal core comprises:
filling the hollow core of the source/drain region with the material of the metal core such that the material of the metal core lands on the bottom isolation layer.

11. A method, comprising:
forming a plurality of nanostructure channels that are arranged in a first direction in a semiconductor device and that extend in a second direction in the semiconductor device that is approximately perpendicular to the first direction;
forming a source/drain region adjacent to the plurality of nanostructure channels in the second direction;
forming a dielectric layer above the source/drain region;
forming a gate structure that wraps around at least three sides of the plurality of nanostructure channels;
forming, from a first side of the semiconductor device, a first contact recess through the dielectric layer and into the source/drain region such that a bottom of the first contact recess is at a depth in the semiconductor device that is lower than a bottom-most nanostructure channel of the plurality of nanostructure channels;
forming a first source/drain contact in the first contact recess such that the source/drain contact extends into the source/drain region;
forming, from a second side of the semiconductor device opposing the first side, a second contact recess that extends into the source/drain region; and
forming a second source/drain contact in the second contact recess such that the second source/drain contact is coupled to the source/drain region.

12. The method of claim 11, wherein forming the first contact recess comprises:
performing a first etch operation to form the first contact recess such that the bottom of the first contact recess is at a first depth in the source/drain region; and
performing a second etch operation to extend the first contact recess from the first depth to the depth that is lower than the bottom-most nanostructure channel.

13. The method of claim 12, further comprising:
forming, after the first etch operation and prior to the second etch operation, a protective liner on sidewalls of the first contact recess and on a top of the source/drain region in the first contact recess; and
performing, after the first etch operation and prior to the second etch operation, a third etch operation to etch through the protective liner to expose the top of the source/drain region through the first contact recess.

14. The method of claim 13, wherein performing the second etch operation comprises:
performing the second etch operation while the protective liner is on the sidewalls of the first contact recess.

15. The method of claim 11, wherein forming the first source/drain contact comprises:
forming a metal silicide layer in the first contact recess; and
forming the first source/drain contact on the metal silicide layer.

16. The method of claim 15, wherein forming the second source/drain contact in the second contact recess comprises:
forming the second source/drain contact in the second contact recess such that the second source/drain contact is in contact with the metal silicide layer.

17. A semiconductor device, comprising:
a plurality of nanostructure channels arranged in a first direction and that extend in a second direction is approximately perpendicular to the first direction;
a gate structure wrapping around the plurality of nanostructure channels;
a source/drain region, adjacent to a side of the gate structure and adjacent to ends of the plurality of nanostructure channels, comprising:
a metal core; and
one or more epitaxial layers laterally surrounding the metal core;
a front side source/drain contact on a front side of the semiconductor device and in electrical connection with a first side of the metal core of the source/drain region; and
a back side source/drain contact on a back side of the semiconductor device and in electrical connection with a second side of the metal core of the source/drain region opposing the first side.

18. The semiconductor device of claim 17, further comprising:
a bottom isolation layer adjacent to the second side of the metal core,
wherein the back side source/drain contact extends through the bottom isolation layer.

19. The semiconductor device of claim 17, further comprising:
a semiconductor buffer region adjacent to the second side of the metal core,
wherein the back side source/drain contact extends through the semiconductor buffer region.

20. The semiconductor device of claim 17, further comprising:
a semiconductor capping layer between the metal core and the one or more epitaxial layers.
